(19) United States
(12) Patent Application Publication
(10) Pub. No.: US 2024/0014166 A1
(43) Pub. Date: Jan. 11, 2024

(54) SEMICONDUCTOR PACKAGE

(71) Applicant: SAMSUNG ELECTRONICS CO., LTD., SUWON-SI (KR)

(72) Inventors: Youngdeuk KIM, Suwon-si (KR); Jaechoon KIM, Suwon-si (KR); Taehwan KIM, Suwon-si (KR); Kyungsuk OH, Suwon-si (KR); Heejung Hwang, Suwon-si (KR)

(21) Appl. No.: 18/218,886

(22) Filed: Jul. 6, 2023

(30) Foreign Application Priority Data
Jul. 8, 2022 (KR) 10-2022-0084564

(51) Int. Cl. H01L 23/00; H01L 25/18; H10B 80/00; H01L 25/00

(52) U.S. Cl. CPC H01L 24/73; H01L 24/05; H01L 24/06; H01L 24/08; H01L 24/13; H01L 24/16; H01L 24/17; H01L 24/32; H01L 24/33; H01L 24/80; H01L 24/81; H01L 24/83; H01L 24/92; H01L 25/18; H10B 80/00; H01L 25/50; H01L 2224/05025; H01L 2224/05155; H01L 2224/05073; H01L 2224/05564; H01L 2224/05573; H01L 2224/05644; H01L 2224/05666; H01L 2224/06181; H01L 2224/05647; H01L 2224/80359; H01L 2924/0544; H01L 2924/059; H01L 2224/06505; H01L 2224/08145; H01L 2224/13111; H01L 2224/13109; H01L 2224/13113; H01L 2224/1312; H01L 2224/13147; H01L 2224/13139; H01L 2224/13118; H01L 2224/13116; H01L 2224/13144; H01L 2924/014; H01L 2224/16145; H01L 2224/17181; H01L 2224/32145; H01L 2224/32013; H01L 2224/33181; H01L 2224/73204; H01L 2224/73253; H01L 2224/80357; H01L 2224/81203; H01L 2224/83203; H01L 2224/9211; H01L 2224/92222; H01L 2224/92242; H01L 2224/80895; H01L 2224/80896; H01L 2224/9222

(57) ABSTRACT

A semiconductor package including: a lower chip; a chip structure including stacked semiconductor chips; and an adhesive film, the semiconductor chips include first bonding chips bonded to each other by bumps and second bonding chips directly bonded to each other, the first bonding chips include: a first bonding lower chip including a first bonding upper pad; and a first bonding upper chip on the first bonding lower chip and including a first bonding lower pad, the second bonding chips include: a second bonding lower chip including a second bonding upper insulating layer and a second bonding upper pad; and a second bonding upper chip on the second bonding lower chip and including a second bonding lower insulating layer, and a second bonding lower pad, and the adhesive film surrounds side surfaces of the bumps, fills a region between the first bonding lower and upper chips, and protrudes from the region.

### CROSS-REFERENCE TO RELATED APPLICATION(S)

This application claims priority under 35 U.S.C. § 119 to Korean Patent Application No. 10-2022-0084564 filed on Jul. 8, 2022 in the Korean Intellectual Property Office, the disclosure of which is incorporated by reference herein in its entirety.

### TECHNICAL FIELD

Example embodiments of the present disclosure relate to a semiconductor package and a method of manufacturing the same.

### DISCUSSION OF RELATED ART

As demand for high capacity, reduced thickness and miniaturized electronic products has increased, various types of semiconductor packages have been developed. Recently, as a method for integrating more components (e.g., semiconductor chips) into a package structure, a technique for vertically stacking semiconductor chips has been developed.

### SUMMARY

An example embodiment of the present disclosure provides a semiconductor package that improves thermal properties and increases yield.

An example embodiment of the present disclosure provides a method of manufacturing the semiconductor package.

According to an example embodiment of the present disclosure, there is provided a semiconductor package including: a lower chip, a stack chip structure on the lower chip, the stack chip structure including semiconductor chips stacked in a direction perpendicular to an upper surface of the lower chip; and an adhesive film, wherein the semiconductor chips include first bonding chips bonded to each other by bumps and second bonding chips directly bonded to each other, wherein the first bonding chips include: a first bonding lower chip including a first bonding upper pad in contact with and bonded to the bumps; and a first bonding upper chip disposed on the first bonding lower chip and including a first bonding lower pad in contact with and bonded to the bumps, wherein the second bonding chips include: a second bonding lower chip including a second bonding upper insulating layer and a second bonding upper pad; and a second bonding upper chip disposed on the second bonding lower chip and including a second bonding lower insulating layer in contact with and bonded to the second bonding upper insulating layer, and a second bonding lower pad in contact with and bonded to the second bonding upper pad, and wherein the adhesive film surrounds side surfaces of the bumps, fills a region between the first bonding lower chip and the first bonding upper chip, and protrudes from the region between the first bonding lower chip and the first bonding upper chip.

According to an example embodiment of the present disclosure, there is provided a semiconductor package including: a lower chip; a stack chip structure on the lower chip, the stack chip structure including semiconductor chips stacked in a direction perpendicular to an upper surface of the lower chip; and an adhesive film, wherein the semiconductor chips include first bonding chips bonded to each other by a bump and second bonding chips directly bonded to each other, wherein the first bonding chips include a first bonding lower chip and a first bonding upper chip connected to the first bonding lower chip by the bump on the first bonding lower chip, wherein the second bonding chips include a second bonding lower chip and a second bonding upper chip directly bonded to the second bonding lower chip, wherein the adhesive film surrounds a side surface of the bump, fills a region between the first bonding lower chip and the first bonding upper chip, and protrudes from side surfaces of at least one of the first bonding lower chip and the first bonding upper chip, wherein one of the first bonding chips and one of the second bonding chips are the same and constitute a shared chip, wherein the shared chip includes: a body portion having a first side and a second side opposite to each other; a first bonding pad disposed on the first side of the body portion: and a second bonding pad and a second bonding insulating layer disposed on the second side of the body portion, wherein the first bonding pad is in contact with the bump, wherein the first bonding pad has a first thickness, and wherein the second bonding pad has a second thickness different from the first thickness.

According to an example embodiment of the present disclosure, there is provided a semiconductor package including: a lower chip; and a stack chip structure on the lower chip, the stack chip structure including semiconductor chips stacked in a direction perpendicular to an upper surface of the lower chip, wherein the semiconductor chips include first bonding chips bonded to each other by a bump and second bonding chips directly bonded to each other, wherein each of the semiconductor chips includes a body portion including a semiconductor substrate and an internal circuit region disposed below the semiconductor substrate, wherein a first semiconductor chip of the semiconductor chips further includes a first bonding pad disposed on a first side of the body portion, and a second bonding pad and a second bonding insulating layer disposed on a second side of the body portion, wherein the second bonding insulating layer covers at least a portion of a side surface of the second bonding pad, wherein a thickness of the first bonding pad is about 2 μm to about 5 μm, and wherein a thickness of the second bonding pad is about 0.3 μm to about 0.9 μm.

According to an example embodiment of the present disclosure, there is provided a method of manufacturing a semiconductor package, the method including: forming a base substrate; and forming a plurality of vertically stacked semiconductor chips on the base substrate using a first bonding process and a second bonding process different from the first bonding process, wherein the plurality of semiconductor chips include first bonding chips bonded to each other by a bump using the first bonding process, and second bonding chips directly bonded to each other using the second bonding process, wherein the forming the first bonding chips includes: forming a first bonding lower chip having a first bonding upper pad; forming a first bonding upper chip having a first bonding lower pad; forming a bump below the first bonding lower pad of the first bonding upper chip; forming an adhesive film in a region below the first bonding upper chip and surrounding the bump; and thermally compressing the first bonding upper chip to the adhesive film on the first bonding lower chip, wherein the first bonding lower chip and the first bonding upper chip are bonded to each other by the bump, and are included in the first bonding chips, wherein the forming the second bonding chips includes: forming a second bonding lower chip including a second bonding upper insulating layer and a second bonding upper pad; forming a second bonding upper chip including a second bonding lower insulating layer and a second bonding lower pad; and bonding the second bonding upper chip to the second bonding lower chip, wherein the second bonding upper pad and the second bonding lower pad are in direct contact with and bonded to each other, and wherein the second bonding upper insulating layer and the second bonding lower insulating layer are in direct contact with and bonded to each other.

### BRIEF DESCRIPTION OF THE DRAWINGS

The above and other features of the present disclosure will be more clearly understood from the following detailed description, taken in combination with the accompanying drawings, in which:

FIGS. 1A, 1B and 1C are cross-sectional diagrams illustrating semiconductor chips included in a semiconductor package according to an example embodiment of the present disclosure;

FIGS. 2A, 2B and 2C are diagrams illustrating an example of a semiconductor package according to an example embodiment of the present disclosure;

FIG. 3 is a cross-sectional diagram illustrating a modified example of a semiconductor package according to an example embodiment of the present disclosure;

FIG. 4 is a cross-sectional diagram illustrating a modified example of a semiconductor package according to an example embodiment of the present disclosure;

FIG. 5 is a cross-sectional diagram illustrating a modified example of a semiconductor package according to an example embodiment of the present disclosure;

FIG. 6 is a cross-sectional diagram illustrating a modified example of a semiconductor package according to an example embodiment of the present disclosure;

FIG. 7 is a cross-sectional diagram illustrating a modified example of a semiconductor package according to an example embodiment of the present disclosure;

FIG. 8 is a cross-sectional diagram illustrating a modified example of a semiconductor package according to an example embodiment of the present disclosure;

FIG. 9 is a cross-sectional diagram illustrating a modified example of a semiconductor package according to an example embodiment of the present disclosure;

FIG. 10 is a cross-sectional diagram illustrating a modified example of a semiconductor package according to an example embodiment of the present disclosure;

FIG. 11 is a cross-sectional diagram illustrating a modified example of a semiconductor package according to an example embodiment of the present disclosure;

FIG. 12 is a cross-sectional diagram illustrating an example of a semiconductor package according to an example embodiment of the present disclosure;

FIG. 13 is a flowchart illustrating processes of a method of manufacturing a semiconductor package according to an example embodiment of the present disclosure;

FIGS. 14, 15A, 15B and 15C are diagrams illustrating an example of a method of manufacturing a semiconductor package according to an example embodiment of the present disclosure;

FIGS. 16, 17A and 17B are diagrams illustrating another example of a method of manufacturing a semiconductor package according to an example embodiment of the present disclosure; and

FIG. 18 is a flowchart illustrating processes of another example of a method of manufacturing a semiconductor package according to an example embodiment of the present disclosure.

### DETAILED DESCRIPTION OF THE EMBODIMENTS

Hereinafter, example embodiments of the present disclosure will be described as follows with reference to the accompanying drawings. In the drawings, like reference numerals refer to like elements.

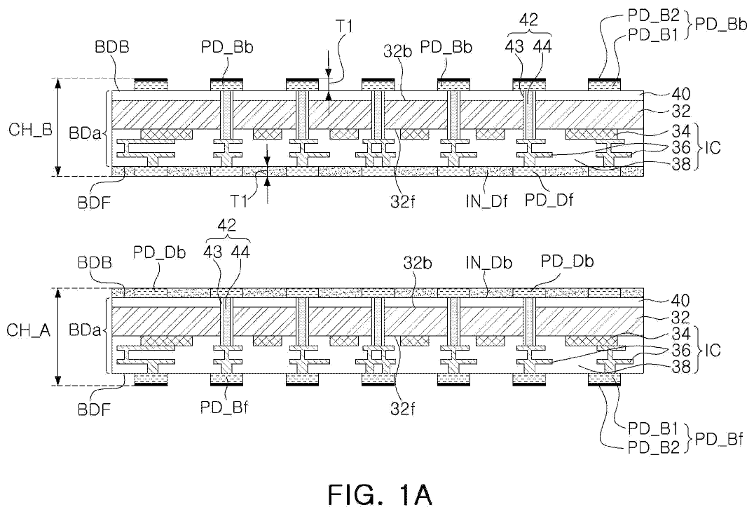

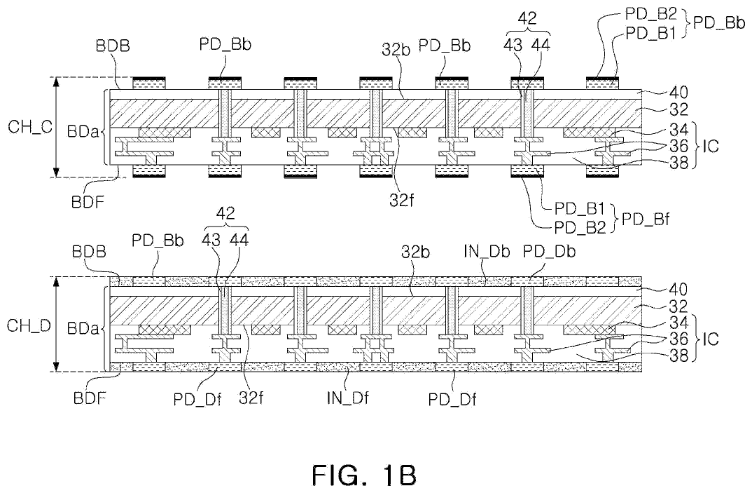

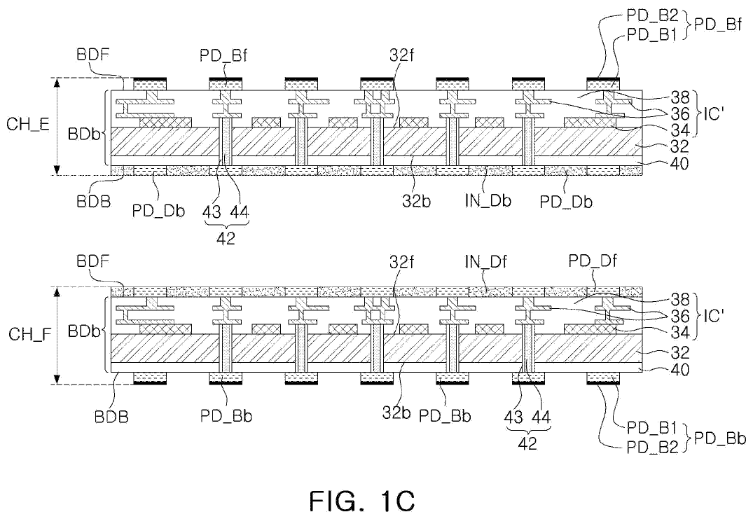

Various types of semiconductor chips included in a semiconductor package will be described according to example embodiments with reference to FIGS. 1A to 1C. FIG. 1A is a cross-sectional diagram illustrating an A-type semiconductor chip and a B-type semiconductor chip included in semiconductor packages in an example embodiment, FIG. 1B is a cross-sectional diagram illustrating a C-type semiconductor chip and a D-type semiconductor chip included in semiconductor packages in an example embodiment, and FIG. 1C is a cross-sectional diagram illustrating an E-type semiconductor chip and an F-type semiconductor chip included in semiconductor packages in an example embodiment.

Referring to FIGS. 1A, 1B, and 1C, a semiconductor package in an example embodiment may include a stack chip structure including least two of an A-type semiconductor chip CH_A, a B-type semiconductor chip CH_B, a C-type semiconductor chip CH_C, a D-type semiconductor chip CH_D, an E-type semiconductor chip CH_E, and an F-type semiconductor chip CH_F.

Each of the A-type semiconductor chip CH_A, the B-type semiconductor chip CH_B, the C-type semiconductor chip CH_C and the D-type semiconductor chip CH_D may include a first body portion BDa.

Each of the E-type semiconductor chip CH_E and the F-type semiconductor chip CH_F may include a second body portion BDb.

The first body portion BDa may include a semiconductor substrate 32, a first internal circuit region IC disposed below the semiconductor substrate 32, and a rear protective layer 40 disposed on the semiconductor substrate 32.

In the first body portion BDa, the first internal circuit region IC may be disposed below a first front surface 32f of the semiconductor substrate 32, and the rear protective layer 40 may be disposed on a first rear surface 32b of the semiconductor substrate 32.

The first body portion BDa may further include a through-electrode structure 42 penetrating through the rear protective layer 40 and the semiconductor substrate 32 and extending into the internal circuit region IC. The through-electrode structure 42 may include a conductive through-electrode 44 and an insulating through-spacer 43 covering a side surface of the through-electrode 44. The first internal circuit region IC may include an internal circuit 34 and interconnections 36 electrically connected to the internal circuit 34. The first internal circuit region IC may further include an insulating structure 38.

The second body portion BDb may include a semiconductor substrate 32, a second internal circuit region IC′ disposed on the semiconductor substrate 32, and a rear protective layer 40 disposed below the semiconductor substrate 32.

In the second body portion BDb, a second internal circuit region IC′ may be disposed on a first front surface 32f of the semiconductor substrate 32, and the rear protective layer 40 may be disposed below a first rear surface 32b of the semiconductor substrate 32. The second body portion BDb may further include a through-electrode structure 42 penetrating through the rear protective layer 40 and the semiconductor substrate 32 and extending into the second internal circuit region IC′. The through-electrode structure 42 may include a conductive through-electrode 44 and an insulating through-spacer 43 covering a side surface of the through-electrode 44. The second internal circuit region IC′ may be substantially the same as the first internal circuit region IC. For example, the second internal circuit region IC′ may include an internal circuit 34 and interconnections 36 electrically connected to the internal circuit 34.

The first body portion BDa may have a front surface BDF and a rear surface BDB opposite to each other. In the first body portion BDa, the front surface BDF may be disposed in a lower portion. The second body portion BDb may have a front surface BDF and a rear surface BDB opposite to each other. In the second body portion BDb, the front surface BDF may be disposed in an upper portion. In the first body portion BDa, the first internal circuit region IC may be disposed below the semiconductor substrate 32, and in the second body portion BDb, the second internal circuit region (IC′) may be disposed above the semiconductor substrate 32.

The “front surface” may be referred to as a “first side” or a “front side”. The “rear surface” may be referred to as a “second side”, a “back side”, or a “backside surface”.

When the semiconductor chips CH_A to CH_F are configured as memory chips, the internal circuit 34 may include a memory cell array and a peripheral circuit. When the semiconductor chips CH_A to CH_F are configured as dynamic random access memory (DRAM) chips, the memory cell array may include a DRAM memory cell, such as, for example, a cell switching device and a DRAM capacitor. When the semiconductor chips CH_A to CH_F are configured as NAND flash memory chips, the memory cell array may include memory cell transistors. The semiconductor chips CH_A to CH_F in the example embodiment are not limited to the aforementioned DRAM chip or NAND flash memory chip, and may be configured as other memory chips or logic chips.

In example embodiments, the term “first bonding pad” may refer to a pad used in a first bonding process, and the terms “second bonding pad” and “second bonding insulating layer” may refer to the pad and the insulating layer used in a second bonding process. For example, the first bonding process may be a thermal compression bonding process, and the second bonding process may be a hybrid metal bonding process. Here, the hybrid metal bonding process may be a direct bonding process of directly bonding a metal to a metal, and directly bonding an insulating layer to an insulating layer.

The A-type semiconductor chip CH_A may include a first bonding pad PD_Bf disposed below the front surface BDF of the first body portion BDa, and a second bonding pad PD_Db and a second bonding insulating layer IN_Db disposed on the rear surface BDB of the first body portion BDa. The second bonding pad PD_Db may be adjacent to the second bonding insulating layer IN—Db in a horizontal direction.

The B-type semiconductor chip CH_B may include a second bonding pad PD_Df and a second bonding insulating layer IN_Df disposed below the front surface BDF of the first body portion BDa, and a first bonding pad PD_Bb disposed on the rear surface BDB of the first body portion BDa.

The C-type semiconductor chip CH_C may include a first bonding pad PD_Bf disposed below the front surface BDF of the first body portion BDa, and a first bonding pad PD_Bb disposed on the rear surface BDB of the first body portion BDa.

The D-type semiconductor chip CH_D may include a second bonding pad PD_Df and a second bonding insulating layer IN_Df disposed below the front surface BDF of the first body portion BDa, and a second bonding pad PD_Db and a second bonding insulating layer IN_Db disposed on the rear surface BDB of the first body portion BDa.

The E-type semiconductor chip CH_E may include a second bonding pad PD_Db and a second bonding insulating layer IN_Db disposed below the rear surface BDB of the second body portion BDb, and a first bonding pad PD_Bf disposed on the front surface BDF of the second body portion BDb.

The F-type semiconductor chip CH_F may include a second bonding pad PD_Df and a second bonding insulating layer IN_Df disposed on the front surface BDF of the second body portion BDb, and a first bonding pad PD_Bb disposed below the rear surface BDB of the second body portion BDb.

The first bonding pad PD_Bb and PD_Bf may include a first conductive layer PD_B1 and a second conductive layer PD_B2 on the first conductive layer PD_B1. The first conductive layer PD_B1 may include Ni, and the second conductive layer PD_B2 may include at least one of Au and Ti.

In an example embodiment, the first bonding pads PD_Bb and PD_Bf may include a first metal material, and the second bonding pads PD_Db and PD_Df may include a second metal material. The first metal material may include at least one of Ni, Au, and Ti, and the second metal material may include Cu.

The second bonding insulating layer IN_Df and IN_Db may include silicon oxide. However, an example embodiment thereof is not limited thereto. For example, the second bonding insulating layers IN_Df and IN_Db may include an insulating material such as silicon carbonitride (SiCN).

In an example embodiment, the first bonding pad PD_Bb and PD_Bf may have a first thickness T1, and the second bonding pad PD_Db and PD_Df may have a second thickness T2 smaller than the first thickness.

The first thickness T1 may be in the range of about 2 μm to about 5 μm.

The second thickness T2 may be in the range of about 0.3 m to about 0.9 μm.

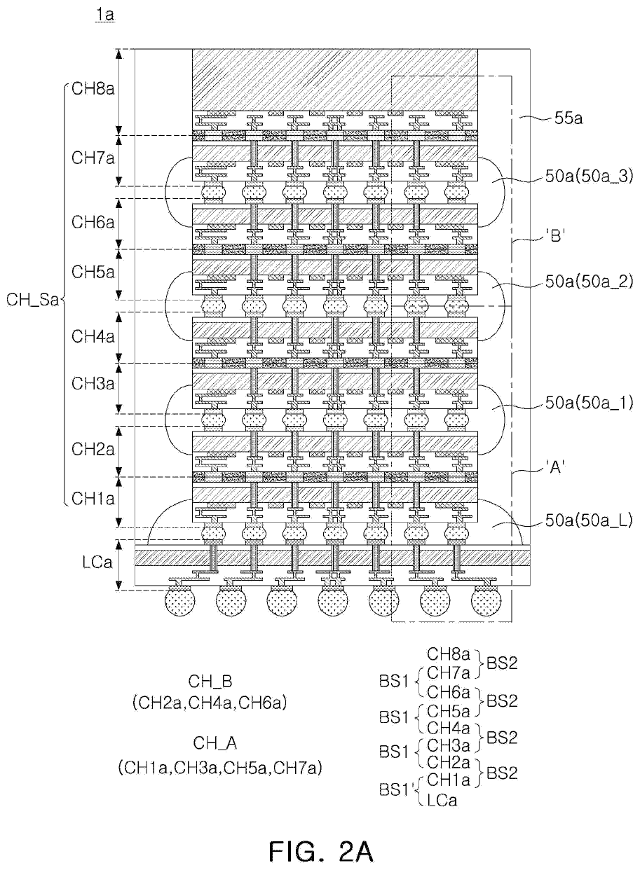

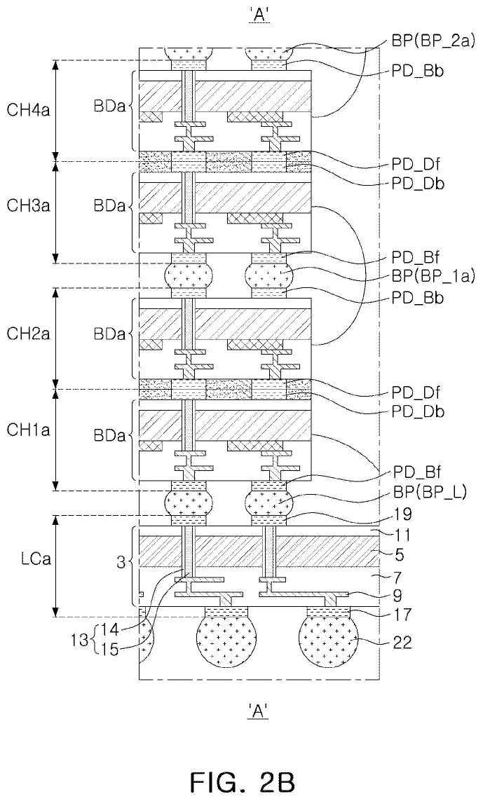

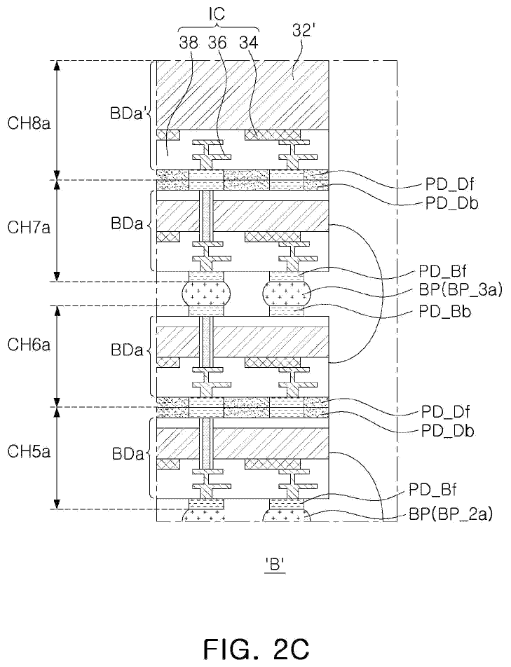

An example embodiment of a semiconductor package will be described with reference to FIGS. 2A to 2C together with FIG. 1A. FIG. 2A is a cross-sectional diagram illustrating a semiconductor package according to an example embodiment, FIG. 2B is an enlarged diagram illustrating region “A” in FIG. 2A, and FIG. 2C is an enlarged diagram illustrating region “B” in FIG. 2A

Referring to FIGS. 2A, 2B and 2C together with FIG. 1A, a semiconductor package 1a according to an example embodiment may include a lower chip LCa, a stack chip structure CH_Sa, an adhesive film 50a and a mold layer 55a.

The lower chip LCa may include a body portion 3, a lower pad 17 below the body portion 3, and an upper pad 19 on the body portion 3. The body portion 3 may include a substrate 5, interconnections 9 disposed below the substrate 5, an insulating structure 7 covering the interconnections 9 below the substrate 5, a protective layer 11 on the substrate 5, and a through-electrode structure 13 penetrating through the protective layer 11 and the substrate 5 and electrically connected to the interconnections 9. The through-electrode structure 13 may include a conductive through-electrode 15 and an insulating through-spacer 14 covering a side surface of the through-electrode 15. In the lower chip LCa, the interconnections 9 and the through-electrode 15 may electrically connect the lower pad 17 and the upper pad 19 to each other. A connection bump 22 may be disposed below the lower pad 17 of the lower chip LCa.

The stack chip structure CH_Sa may include semiconductor chips BS1 and BS2 stacked in a vertical direction perpendicular to the upper surface of the lower chip LCa.

The semiconductor chips BS1 stacked in the vertical direction may include first bonding chips BS1 bonded to each other by bumps BP and second bonding chips BS2 directly bonded to each other.

The first bonding chips BS1 bonded to each other by the bump BP may include a first bonding lower chip CH_B including a first bonding upper pad PD_Bb in contact with and bonded to the bump BP, and a first bonding upper chip CH_A disposed on the first bonding lower chip CH_B, and including a first bonding lower pad PD_Bf in contact with and bonded to the bump BP. The adhesive film 50a may surround the side surface of the bump BP and may fill a region between the first bonding lower chip CH_B and the first bonding upper chip CH_A, and may extend to side surfaces of the first bonding lower chip CH_B and the first bonding upper chip CH_A. For example, the adhesive film 50a may protrude from side surfaces of the first bonding lower chip CH_B and the first bonding upper chip CH_A.

The adhesive film 50a may be a non-conductive film (NCF), but an example embodiment thereof is not limited thereto, and may include, for example, any type of polymer film able to undergo a thermal compression bonding process.

The bump BP may include solder. The solder may include tin (Sn), indium (In), bismuth (Bi), antimony (Sb), copper (Cu), silver (Ag), zinc (Zn), lead (Pb) and/or alloys thereof. The alloy may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, Sn—Bi—Zn, or the like.

The directly bonded second bonding chips BS2 may include a second bonding lower chip CH_A including a second bonding upper insulating layer IN_Db and a second bonding upper pad PD_Db, and a second bonding upper chip CH_B including a second bonding lower insulating layer IN_Df in contact with and bonded to the second bonding upper insulating layer IN_Db, and a second bonding lower pad PD_Df in contact with and bonded to the second bonding upper pad PD_Db.

In the first bonding chips BS1, the first bonding upper chip CH_A may be the A-type semiconductor chip described with reference to FIG. 1A, and the first bonding lower chip CH_B may be the B-type semiconductor chip described with reference to FIG. 1A. In the second bonding chips BS2, the second bonding upper chip CH_B may be the B-type semiconductor chip described with reference to FIG. 1A, and the second bonding lower chip CH_A may be the A-type semiconductor chip described with reference to FIG. 1A. Accordingly, the stack chip structure CH_Sa may include the A-type semiconductor chip CH_A, the B-type semiconductor chip CH_B, the A-type semiconductor chip CH_A, and the B-type semiconductor chip CH_B stacked in order and bonded to each other.

In the stack chip structure CH_Sa, the number of the plurality of semiconductor chips may be eight or more. For example, the plurality of semiconductor chips may be 12 or more.

A plurality of the first bonding chips may be provided, and a plurality of the second bonding chips may be provided. The plurality of semiconductor chips may include a first chip CH1a, a second chip CH2a, a third chip CH3a, a fourth chip CH4a, a fifth chip CH5a, a sixth chip CH6a, a seventh chip CH7a, and an eighth chip CH8a stacked in order in the vertical direction.

The first chip CH1a and the second chip CH2a may be directly bonded to each other and may be included in the second bonding chips BS2, and the second chip CH2a and the third chip CH3a may be bonded to each other by a first bump BP_1a and may be included in the first bonding chips BS1. The third chip CH3a and the fourth chip CH4a may be directly bonded to each other, and may be included in the second bonding chips BS2. The fourth chip CH4a and the fifth chip CH5a may be bonded to each other by a second bump BP_2a, and may be included in the first bonding chips BS1. The fifth chip CH5a and the sixth chip CH6a may be directly bonded to each other, and may be included in the second bonding chips BS2. The sixth chip CH6a and the seventh chip CH7a may be bonded to each other by the third bump BP_3a and may be included in the first bonding chips BS1. The seventh chip CH7a and the eighth chip CH8a may be directly bonded to each other and may be included in the second bonding chips BS2.

The eighth chip CH8a may be referred to as a capping semiconductor chip.

In an example, the eighth chip CH8a may be substantially the same as the B-type semiconductor chip CH_B. In another example, the eighth chip CH8a may be a capping semiconductor chip from which the through-electrode structure 42 and the first bonding pad PD_Bb are not provided and the semiconductor substrate 32 has an increased thickness in the B-type semiconductor chip CH_B. In this configuration, the eighth chip CH8a may have a modified first body portion BDa′.

The first chip CH1a, the third chip CH3a, the fifth chip CH5a, and the seventh chip CH7a may be the A-type semiconductor chip CH_A described with reference to FIG. 1A, and the second chip CH2a, the fourth chip CH4a, and the sixth chip CH6a may be the B-type semiconductor chip CH_B described with reference to FIG. 1A.

Among the second chip CH2a and the third chip CH3a included in the first bonding chips BS1, the second chip CH2a may be the first bonding lower chip, and, the third chip CH3a may be the first bonding upper chip. Among the fourth chip CH4a and the fifth chip CH5a included in the first bonding chips BS1, the fourth chip CH4a may be the first bonding lower chip, and the fifth chip CH5a may be the first bonding upper chip. Among the sixth chip CH6a and the seventh chip CH7a included in the first bonding chips BS1, the sixth chip CH6a may be the first bonding lower chip, and the seventh chip CH7a may be the first bonding upper chip.

Among the first chip CH1a and the second chip CH2a included in the second bonding chips BS2, the first chip CH1a may be the second bonding lower chip, and, the second chip CH2a may be the second bonding upper chip. Among the third chip CH3a and the fourth chip CH4a included in the second bonding chips BS2, the third chip CH3a may be the second bonding lower chip, and the fourth chip CH4a may be the second bonding upper chip. Among the fifth chip CH5a and the sixth chip CH6a included in the second bonding chips BS2, the fifth chip CH5a may be the second bonding lower chip, and sixth chip CH6a may be the second bonding upper chip. Among the seventh chip CH7a and the eighth chip CH8a included in the second bonding chips BS2, the seventh chip CH7a may be the second bonding lower chip, and the eighth chip CH8a may be the second bonding upper chip.

The second chip CH2a may be the second bonding upper chip among the first chip CH1a and the second chip CH2a included in the second bonding chips BS2, and may be the first bonding lower chip among the second chip CH2a and the third chip CH3a included in the first bonding chips BS1. Accordingly, since the second chip CH2a may be the second bonding upper chip and the first bonding lower chip, the second chip CH2a may be a shared chip of the first bonding chips BS1 and the second bonding chips BS2. The third chip CH3a may be the first bonding upper chip among the second chip CH2a and the third chip CH3a included in the first bonding chips BS1, and may be the second bonding lower chip among the third chip CH3a and the fourth chip CH4a included in the bonding chips BS2. Accordingly, since the third chip CH3a may be the first bonding upper chip and the second bonding lower chip, the third chip CH3a may be a shared chip of the first bonding chips BS1 and the second bonding chips BS2 Similarly, each of the fourth chip CH4a, the fifth chip CH5a, the sixth chip CH6a, and the seventh chip CH7a may be a shared chip of the first bonding chips BS1 and the second bonding chips BS2.

The adhesive film 50a may include a first adhesive film 50a_1 surrounding a side surface of the first bump BP_1a, filling a region between the second chip CH2a and the third chip CH3a, and extending to side surfaces of the second chip CH2a and the third chip CH3a, a second adhesive film 50a_2 surrounding the side surface of the second bump BP_2a, filling a region between the fourth chip CH4a and the fifth chip CH5a, and extending to side surfaces of the fourth chip CH4a and the fifth chip CH5a, and a third adhesive film 50a_3 surrounding the side surfaces of the third bump BP_3a, filling a region between the sixth chip CH6a and the seventh chip CH7a and extending to side surfaces of the sixth chip CH6a and the seventh chip CH7a.

The adhesive film 50a may include an epoxy mold compound (EMC), but the material of the adhesive film 50a is not limited to any particular example.

The first adhesive film 50a_1, the second adhesive film 50a_2, and the third adhesive film 50a_3 may be spaced apart from each other in the vertical direction.

The first chip CH1a and the lower chip LCa may be bonded to each other by a lower bump BPL. Accordingly, the first chip CH1a and the lower chip LCa may be lower bonding chips BS1′ bonded to each other by the lower bump BP_L, similarly to the first bonding chips BS1.

The adhesive film 50a may further include a lower adhesive film 50a_L surrounding the side surface of the lower bump BP_L, filling a region between the first chip CH1a and the lower chip LCa, and extending to the side surface of the first chip CH1a.

The mold layer 55a may cover the side surface of the stack chip structure CH_Sa and may cover the adhesive film 50a on the lower chip LCa.

Hereinafter, various modified examples of the components of the above-described embodiment will be described. Various modifications of the components of the above-described embodiment to be described below will be mainly described with respect to the components being modified or the components being replaced. In addition, the components which may be modified or replaced described below are described with reference to the following drawings, and the components modified or replaced may be combined with each other, or may be combined with the components described above and may be included in the semiconductor device according to an example embodiment.

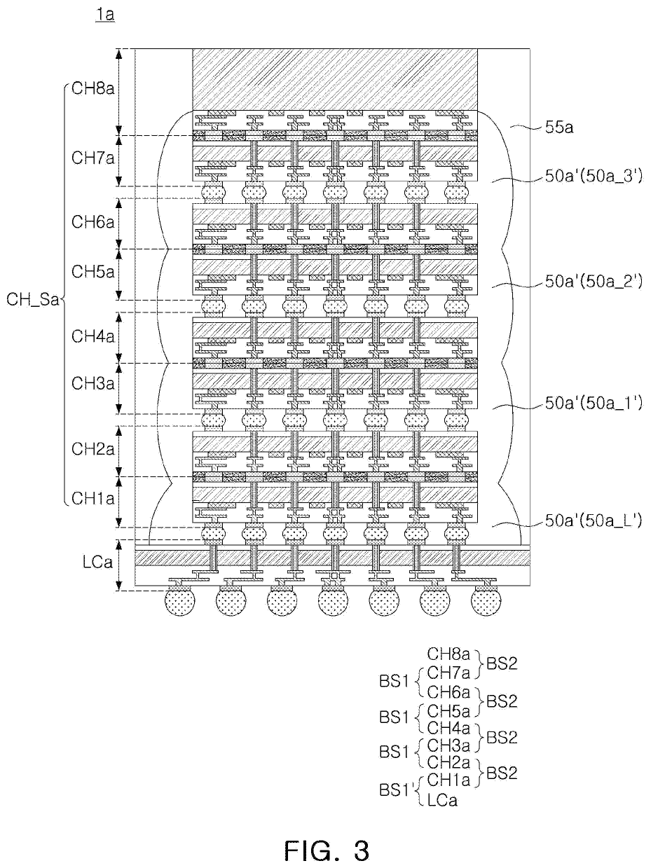

FIG. 3 is a cross-sectional diagram illustrating a modified example of a semiconductor package according to an example embodiment, illustrating a modified example of the adhesive film 50a in FIGS. 2A to 2C.

In a modified example, referring to FIG. 3, the adhesive film 50a in FIGS. 2A to 2C may include the lower adhesive film 50a_L, the first adhesive film 50a_1, the second adhesive film 50a_2, and the third adhesive film 50a_3 spaced apart from each other in the vertical direction, but an example embodiment thereof is not limited thereto. For example, the lower adhesive film 50a_L, the first adhesive film 50a_1, the second adhesive film 50a_2, and the third adhesive film 50a_3 described with reference to FIGS. 2A to 2C may be modified into a lower adhesive film 50a_L′, a first adhesive film 50a_1′, a second adhesive film 50a_2′, and a third adhesive film 50a_3′ connected to each other as illustrated in FIG. 3. Accordingly, as in FIG. 3, the adhesive film 50a in FIGS. 2A to 2C may be modified to an adhesive film 50a′ including the lower adhesive film 50a_L′, the first adhesive film 50a_1′, and the second adhesive film 50a_2′ and the third adhesive film 50a_3. In other words, the lower adhesive film 50a_L′, the first adhesive film 50a_1′, and the second adhesive film 50a_2′ and the third adhesive film 50a_3 may not be spaced apart from each other.

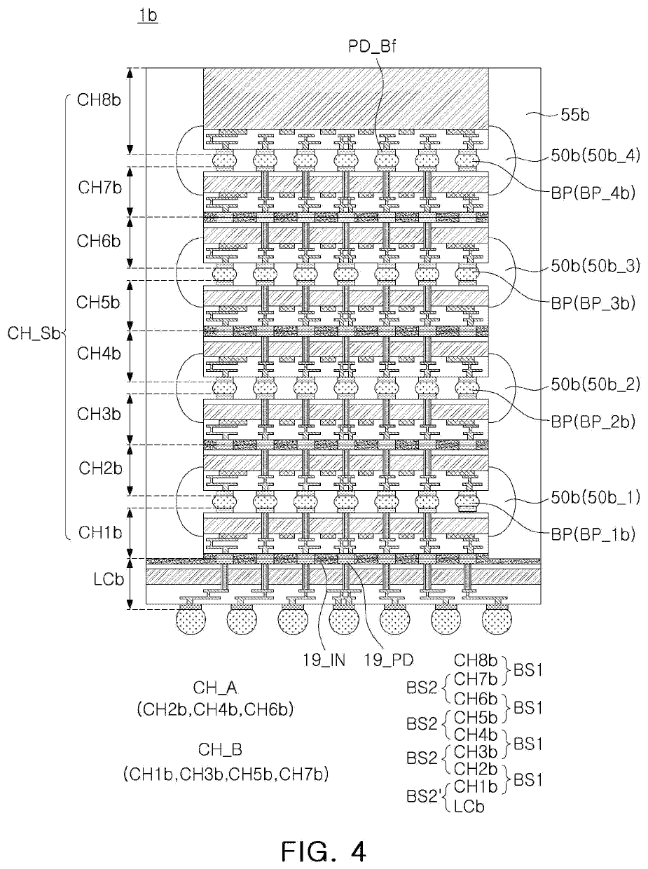

In the description below, a modified example of the semiconductor package will be described according to an example embodiment with reference to FIG. 4 together with FIG. 1A. FIG. 4 is a cross-sectional diagram illustrating a modified example of a semiconductor package according to an example embodiment.

In the modified example, referring to FIG. 4 together with FIG. 1A, the semiconductor package 1b in the modified example may include a lower chip LCb, a stack chip structure CH_Sb, an adhesive film 50b and a mold layer 55b.

The lower chip LCb may include the body portion 3 substantially the same as in FIGS. 2A to 2C, and the lower pad 17 below the body portion 3.

The lower chip LCb may further include an upper pad 19_PD and an upper bonding insulating layer 19_IN having upper surfaces coplanar on the body portion 3.

The stack chip structure CH_Sb may include semiconductor chips BS1 and BS2 stacked in a vertical direction perpendicular to the upper surface of the lower chip LCb.

In the stack chip structure CH_Sb, the vertically stacked semiconductor chips BS1 and BS2 may include first bonding chips BS1 bonded to each other by a bump BP and second bonding chips BS2 directly bonded to each other.

The first bonding chips BS1 bonded to each other by the bump BP may include a first bonding lower chip CH_B including a first bonding upper pad PD_Bb in contact with and bonded to the bump BP, and a first bonding upper chip CH_A including a first bonding lower pad PD_Bf in contact with and bonded to the bump BP.

The adhesive film 50b may surround the side surface of the bump BP and may fill a region between the first bonding lower chip CH_B and the first bonding upper chip CH_A, and may extend to side surfaces of the first bonding lower chip CH_B and the first bonding upper chip CH_A.

The directly bonded second bonding chips BS2 may include a second bonding lower chip CH_A including a second bonding upper insulating layer IN_Db and a second bonding upper pad PD_Db, and a second bonding upper chip CH_B disposed on the bonding lower chip CH_A, the second bonding upper chip CH_B including a second bonding lower insulating layer IN_Df in contact with and bonded to the second bonding upper insulating layer IN_Db and the second bonding lower pad PD_Df in contact with and bonded to the second bonding upper pad PD_Db.

In the first bonding chips BS1, the first bonding upper chip CH_A may be the A-type semiconductor chip described with reference to FIG. 1A, and the first bonding lower chip CH_B may be the B-type semiconductor chip described with reference to FIG. 1A. In the second bonding chips BS2, the second bonding upper chip CH_B may be the B-type semiconductor chip described with reference to FIG. 1A, and the second bonding lower chip CH_A may be the A-type semiconductor chip described with reference to FIG. 1A.

The stack chip structure CH_Sa may include the B-type semiconductor chip CH_B, the A-type semiconductor chip CH_A, the B-type semiconductor chip CH_B, and the A-type semiconductor chip CH_A stacked in order and bonded to each other.

In the stack chip structure CH_Sb, the number of the plurality of semiconductor chips may be eight or more. A plurality of the first bonding chips may be provided, and a plurality of the second bonding chips may be provided. The plurality of semiconductor chips may include a first chip CH1b, a second chip CH2b, a third chip CH3b, a fourth chip CH4b, a fifth chip CH5b, a sixth chip CH6b, a seventh chip CH7b, and an eighth chip CH8b stacked in order in the vertical direction.

The first chip CH1b and the second chip CH2b may be bonded to each other by a first bump BP_1b and may be included in the first bonding chips BS1, and the second chip CH2b and the third chip CH3b may be directly bonded to each other and may be included in the second bonding chips BS2. The third chip CH3b and the fourth chip CH4b may be bonded to each other by a second bump BP_2b and may be included in the first bonding chips BS1. The fourth chip CH4b and the fifth chip CH5b may be directly bonded to each other, and may be included in the second bonding chips BS2. The fifth chip CH5b and the sixth chip CH6b may be bonded to each other by a third bump BP_3b and may be included in the first bonding chips BS1. The sixth chip CH6b and the seventh chip CH7b may be directly bonded to each other and may be included in the second bonding chips BS2. The seventh chip CH7b and the eighth chip CH8b may be bonded to each other by a fourth bump BP_4b, and may be included in the first bonding chips BS1.

The eighth chip CH8b may be referred to as a capping semiconductor chip.

In an example, the eighth chip CH8b may be substantially the same as the A-type semiconductor chip CH_A. In another example, the eighth chip CH8b may be a capping semiconductor chip in which the through-electrode structure 42, the second bonding pad PD_Db, and the second bonding insulating layer IN_Db are not provided and the semiconductor substrate 32 has an increased thickness in the A-type semiconductor chip CH_A.

The first chip CH1b, the third chip CH3b, the fifth chip CH5b, and the seventh chip CH7b may be the B-type semiconductor chip CH_B described with reference to FIG. 1A, and the second chip CH2b, the fourth chip CH4b, and the sixth chip CH6b may be the A-type semiconductor chip CH_A described with reference to FIG. 1A.

Among the first chip CH1b and the second chip CH2b included in the first bonding chips BS1, the first chip CH1b may be the first bonding lower chip, and, the second chip CH2b may be the first bonding upper chip. Among the third chip CH3b and the fourth chip CH4b included in the first bonding chips BS1, the third chip CH3b may be the first bonding lower chip, and the fourth chip CH4b may be the first bonding upper chip. Among the fifth chip CH5b and the sixth chip CH6b included in the first bonding chips BS1, the fifth chip CH5b may be the first bonding lower chip, and the sixth chip CH6b may be the first bonding upper chip. Among the seventh chip CH7b and the eighth chip CH7b included in the first bonding chips BS1, the seventh chip CH7b may be the first bonding lower chip, and the eighth chip CH8b may be the first bonding upper chip.

Among the second chip CH2b and the third chip CH3b included in the second bonding chips BS2, the second chip CH2b may be the second bonding lower chip, and, the third chip CH3b may be the second bonding upper chip. Among the fourth chip CH4b and the fifth chip CH5b included in the second bonding chips BS2, the fourth chip CH4b may be the second bonding lower chip, and the fifth chip CH5b may be the second bonding upper chip. Among the sixth chip CH6b and the seventh chip CH7b included in the second bonding chips BS2, the sixth chip CH6b may be the second bonding lower chip, and the seventh chip CH7b may be the second bonding upper chip.

The second chip CH2b may be the first bonding upper chip among the first chip CH1b and the second chip CH2b included in the first bonding chips BS1, and may be the second bonding lower chip among the second chip CH2b and the third chip CH3b included in the second bonding chips BS2. Accordingly, since the second chip CH2b may be the first bonding upper chip and the second bonding lower chip, the second chip CH2b may be a shared chip of the first bonding chips BS1 and the second bonding chips BS2. Similarly, each of the third chip CH3b, the fourth chip CH4b, the fifth chip CH5b, the sixth chip CH6b, and the seventh chip CH7b may be a shared chip of the first bonding chips BS1 and the second bonding chips BS2.

The adhesive film 50b may include a first adhesive film 50b_1 surrounding a side surface of the first bump BP_1b, filling a region between the first chip CH1b and the second chip CH2b, and extending to side surfaces of the first chip CH1b and the second chip CH2b, a second adhesive film 50b_2 surrounding the side surface of the second bump BP_2b, filling a region between the third chip CH3b and the fourth chip CH4b, and extending to side surfaces of the third chip CH3b and the fourth chip CH4b, a third adhesive film 50b_3 surrounding the side surfaces of the third bump BP_3b, filling a region between the fifth chip CH5b and the sixth chip CH6b, and extending to side surfaces of the fifth chip CH5b and the sixth chip CH6b, and a fourth adhesive film 50b_4 surrounding the fourth bump BP_4b, filling a region between the seventh chip CH7b and the eighth chip CH8b, and extending to the side surfaces of the seventh chip CH7b and the eighth chip CH8b.

The first adhesive film 50b_1, the second adhesive film 50b_2, the third adhesive film 50b_3, and the fourth adhesive film 50b_4 may be spaced apart from each other in the vertical direction. For example, the first adhesive film 50b_1, the second adhesive film 50b_2, the third adhesive film 50b_3, and the fourth adhesive film 50b_4 may not contact each other.

The first chip CH1b and the lower chip LCb may be lower bonding chips BS2′ directly bonded to each other. For example, similarly to the second bonding chips BS2, the second bonding pad PD_Df and the second bonding insulating layer IN_Df of the first chip CH1b, in other words, the B-type semiconductor chip CH_B, may be directly bonded to the upper pad 19_PD and the upper bonding insulating layer 19_IN of the lower chip LCb.

The mold layer 55b may cover the side surface of the stack chip structure CH_Sb and the adhesive film 50b on the lower chip LCb.

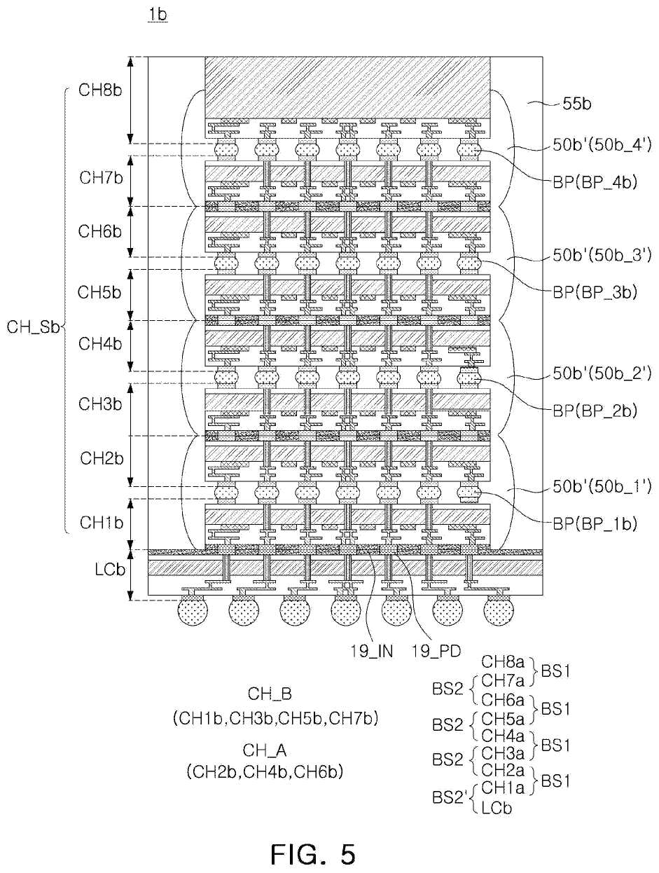

FIG. 5 is a cross-sectional diagram illustrating a modified example of a semiconductor package according to an example embodiment, illustrating a modified example of the adhesive film 50b in FIG. 4.

In a modified example, referring to FIG. 5, the adhesive film 50b in FIG. 4 may include the first adhesive film 50b_1, the second adhesive film 50b_2, the third adhesive film 50b_3 and the fourth adhesive film 50b4 spaced apart from each other in the vertical direction, but an example embodiment thereof is not limited thereto. For example, the first adhesive film 50b_1, the second adhesive film 50b_2, the third adhesive film 50b_3, and the fourth adhesive film 50b_4 spaced apart from each other described with reference to FIG. 4 may be modified to a first adhesive film 50b_1′, a second adhesive film 50b_2′, a third adhesive film 50b_3′, and a fourth adhesive film 50b_4′ connected to each other as in FIG. 5. Accordingly, as in FIG. 5, the adhesive film 50b in FIG. 4 may be modified to an adhesive film 50b′ including the first adhesive film 50b_1′, the second adhesive film 50b_2′, and the third adhesive film 50b_3′, the fourth adhesive film 50b_4′ connected to each other.

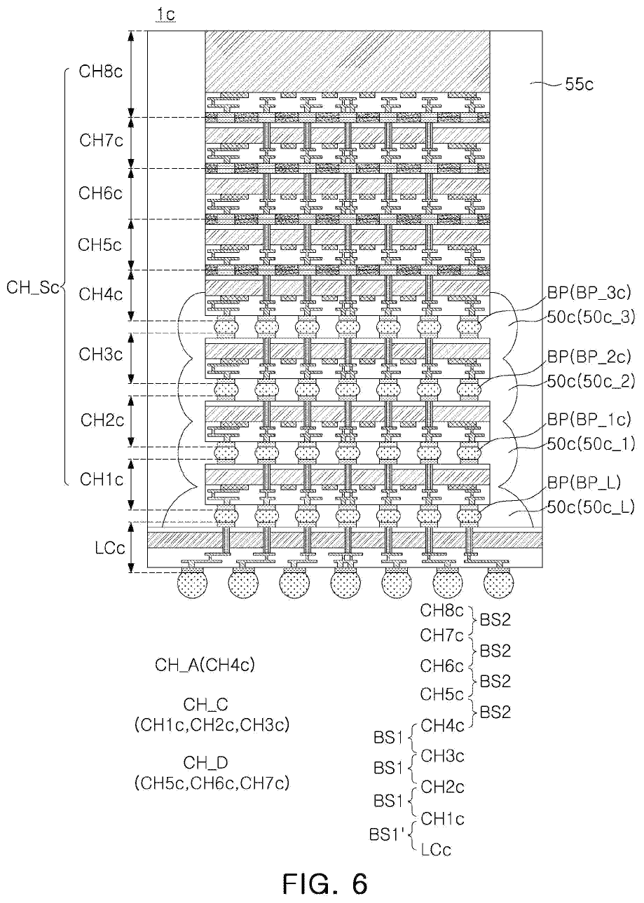

A modified example of a semiconductor package will be described with reference to FIG. 6 together with FIGS. 1A and 1B according to an example embodiment. FIG. 6 is a cross-sectional diagram illustrating a modified example of a semiconductor package according to an example embodiment.

In the modified example, referring to FIG. 6 together with FIGS. 1A and 1B, the semiconductor package 1c in the modified example may include a lower chip LCc, a stack chip structure CH_Sc, an adhesive film 50c and a mold layer 55c.

The lower chip LCc may be substantially the same as the lower chip LCa described with reference to FIGS. 2A to 2C.

The stack chip structure CH_Sc may include semiconductor chips BS1 and BS2 stacked in a vertical direction perpendicular to the upper surface of the lower chip LCc.

In the stack chip structure CH_Sc, the semiconductor chips BS1 stacked in the vertical direction may include first bonding chips BS1 bonded to each other by bumps BP and second bonding chips BS2 directly bonded to each other.

In the stack chip structure CH_Sc, the number of the plurality of semiconductor chips may be eight or more. A plurality of the first bonding chips may be provided, and a plurality of the second bonding chips may be provided. The plurality of semiconductor chips may include a first chip CH1c, a second chip CH2c, a third chip CH3c, a fourth chip CH4c, a fifth chip CH5c, a sixth chip CH6c, a seventh chip CH7c, and an eighth chip CH8c stacked in order in the vertical direction.

The first chip CH1c and the second chip CH2c may be bonded to each other by a first bump BP_1c and may be included in the first bonding chips BS1. The second chip CH2c and the third chip CH3c may be bonded to each other by a second bump BP_2c and may be included in the first bonding chips BS1. The third chip CH3c and the fourth chip CH4c may be bonded to each other by the third bump BP_3c and may be included in the first bonding chips BS1. The fourth chip CH4c and the fifth chip CH5c may be directly bonded to each other, and may be included in the second bonding chips BS2. The fifth chip CH5c and the sixth chip CH6c may be directly bonded to each other, and may be included in the second bonding chips BS2. The sixth chip CH6c and the seventh chip CH7c may be directly bonded to each other, and may be included in the second bonding chips BS2. The seventh chip CH7c and the eighth chip CH8c may be directly bonded to each other, and may be included in the second bonding chips BS2.

The eighth chip CH8c may be referred to as a capping semiconductor chip.

In an example, the eighth chip CH8c may be substantially the same as the D-type semiconductor chip CH_D described with reference to FIG. 1B. In another example, the eighth chip CH8c may be a capping semiconductor chip in which the through-electrode structure 42, the second bonding pad PD_Db, and the second bonding insulating layer IN_Db may not be provided and the semiconductor substrate 32 may have an increased thickness in the D-type semiconductor chip CH_D.

In an example embodiment, the first chip CH1c, the second chip CH2c, and the third chip CH3c may be the C-type semiconductor chip CH_C described with reference to FIG. 1B. The fourth chip CH4c may be the A-type semiconductor chip CH_A described with reference to FIG. 1A. The fifth chip CH5c, the sixth chip CH6c, and the seventh chip CH7c may be the D-type semiconductor chip CH_D described with reference to FIG. 1B. Accordingly, the first chip CH1c, the second chip CH2c, the third chip CH3c, the fourth chip CH4c, the fifth chip CH5c, and the sixth chip CH6c, the seventh chip CH7c, and the eighth chip CH8c stacked in order may be the C-type semiconductor chip CH_C, the C-type semiconductor chip CH_C, the C-type semiconductor chip CH_C, and the A-type semiconductor chip CH_A, the D-type semiconductor chip CH_D, the D-type semiconductor chip CH_D, the D-type semiconductor chip CH_D, and the capping semiconductor chip CH8c stacked in order. The capping semiconductor chip CH8c may have a structure the same as or similar to that of the D-type semiconductor chip CH_D.

The first bonding chips BS1 bonded to each other by the bump BP may include a first bonding lower chip including a first bonding upper pad PD_Bb in contact with and bonded to the bump BP, and a first bonding upper chip disposed on the first bonding lower chip, and including a first bonding lower pad PD_Bf in contact with and bonded to the bump BP.

The directly bonded second bonding chips BS2 may include a second bonding lower chip including a second bonding upper insulating layer IN_Db and a second bonding upper pad PD_Db, and a second bonding upper chip disposed on the second bonding lower chip and including a second bonding lower insulating layer IN_Df in contact with and bonded to the second bonding upper insulating layer IN_Db and a second bonding lower pad PD_Df in contact with and bonded to the second bonding upper pad PD_Db.

Among the first chip CH1c and the second chip CH2c included in the first bonding chips BS1, the first chip CH1c may be the first bonding lower chip, and the second chip CH2c may be the first bonding upper chip. Among the second chip CH2c and the third chip CH3c included in the first bonding chips BS1, the second chip CH2c may be the first bonding lower chip, and the third chip CH3c may be the first bonding upper chip. Among the third chip CH3c and the fourth chip CH4c included in the first bonding chips BS1, the third chip CH3c may be the first bonding lower chip, and the fourth chip CH4c may be the first bonding upper chip.

Among the fourth chip CH4c and the fifth chip CH5c included in the second bonding chips BS2, the fourth chip CH4c may be the second bonding lower chip, and the fifth chip CH5c may be the second bonding upper chip. Among the fifth chip CH5c and the sixth chip CH6c included in the second bonding chips BS2, the fifth chip CH5c may be the second bonding lower chip, and the sixth chip CH6c may be the second bonding upper chip. Among the sixth chip CH6c and the seventh chip CH7c included in the second bonding chips BS2, the sixth chip CH6c may be the second bonding lower chip, and the seventh chip CH7c may be the second bonding upper chip. Among the seventh chip CH7c and the eighth chip CH8c included in the second bonding chips BS2, the seventh chip CH7c may be the second bonding lower chip, and the eighth chip CH8c may be the second bonding upper chip.

The fourth chip CH4c may be the first bonding upper chip among the third chip CH3c and the fourth chip CH4c included in the first bonding chips BS1, and may be the second bonding lower chip among the fourth chip CH4c and the fifth chip CH5c included in the second bonding chips BS2. Accordingly, since the fourth chip CH4c may be the first bonding upper chip and the second bonding lower chip, the fourth chip CH4c may be a shared chip of the first bonding chips BS1 and the second bonding chips BS2.

The adhesive film 50c may surround the side surface of the bump BP, may fill a region between the first bonding lower chip and the first bonding upper chip, and may extend to side surfaces of the first bonding lower chip and the first bonding upper chip. For example, the adhesive film 50c may include a first adhesive film 50c_1 surrounding a side surface of the first bump BP_1c, filling a region between the first chip CH1c and the second chip CH2c, and extending to side surfaces of the first chip CH1c and the second chip CH2c, a second adhesive film 50c_2 surrounding a side surface of the second bump BP_2c, filling a region between the second chip CH2c and the third chip CH3c and extending to side surfaces of the second chip CH2c and the third chip CH3c, and a third adhesive film 50c_3 surrounding the side surfaces of the third bump BP_3c, filling a region between the third chip CH3c and the fourth chip CH4c, and extending to side surfaces of the third chip CH3c and the fourth chip CH4c.

The first chip CH1c and the lower chip LCc may be bonded to each other by a lower bump BP_L. Accordingly, the first chip CH1c and the lower chip LCc may be lower bonding chips BS1′ bonded to each other by the lower bump BP_L, similarly to the first bonding chips BS1.

The adhesive film 50c may further include a lower adhesive film 50c_L surrounding the side surface of the lower bump BP_L, filling a region between the first chip CH1c and the lower chip LCc, and extending to the side surface of the first chip CH1c.

The lower adhesive film 50c_L, the first adhesive film 50c_1, the second adhesive film 50c_2, and the third adhesive film 50c_3 may be connected to each other. In other words, the lower adhesive film 50c_L, the first adhesive film 50c_1, the second adhesive film 50c_2, and the third adhesive film 50c_3 may not be separated from each other.

The mold layer 55c may cover the side surface of the stack chip structure CH_Sa and may cover the adhesive film 50c on the lower chip LCa.

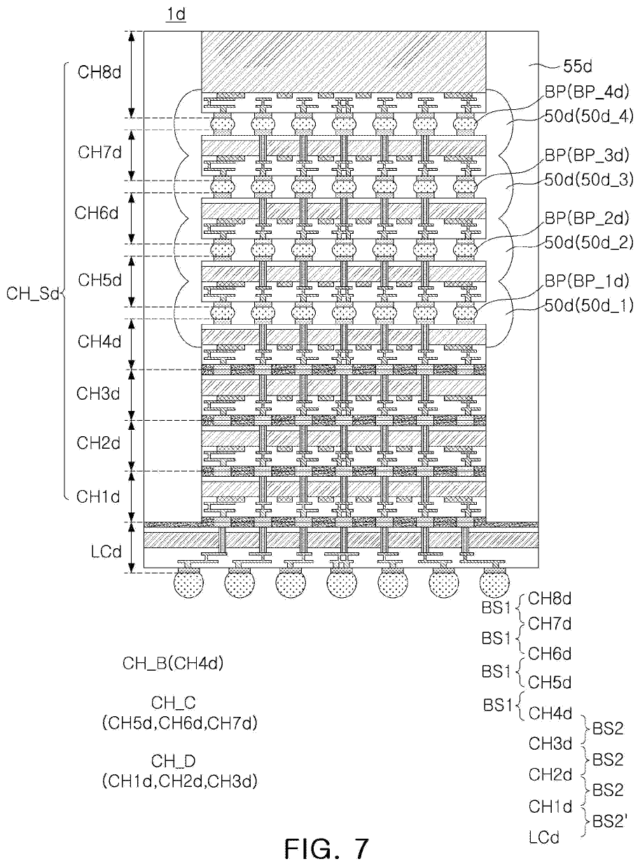

A modified example of a semiconductor package according to an example embodiment will be described with reference to FIG. 7 along with FIGS. 1A and 1B. FIG. 7 is a cross-sectional diagram illustrating a modified example of a semiconductor package according to an example embodiment.

In a modified example, referring to FIG. 7 together with FIGS. 1A and 1B, the semiconductor package 1d in the modified example may include a lower chip LCd, a stack chip structure CH_Sd, an adhesive film 50d and a mold layer 55d.

The lower chip LCd may be substantially the same as the lower chip LCb described with reference to FIG. 4.

The stack chip structure CH_Sd may include semiconductor chips BS1 and BS2 stacked in a vertical direction perpendicular to the upper surface of the lower chip LCd.

In the stack chip structure CH_Sd, the semiconductor chips BS1 stacked in the vertical direction may include first bonding chips BS1 bonded to each other by a bump BP and second bonding chips BS2 directly bonded to each other.

In the stack chip structure CH_Sd, the number of the plurality of semiconductor chips may be eight or more. A plurality of the first bonding chips BS1 may be provided, and a plurality of the second bonding chips BS2 may be provided. The plurality of semiconductor chips may include a first chip CH1d, a second chip CH2d, a third chip CH3d, a fourth chip CH4d, a fifth chip CH5d, a sixth chip CH6d, a seventh chip CH7d, and an eighth chip CH8d stacked in order in the vertical direction.

The first chip CH1d and the second chip CH2d may be directly bonded to each other and may be included in the second bonding chips BS2, and the second chip CH2d and the third chip CH3d may be directly bonded to each other and may be included in the second bonding chips BS2. The third chip CH3d and the fourth chip CH4d may be directly bonded to each other, and may be included in the second bonding chips BS2, and the fourth chip CH4d and the fifth chip CH5d may be bonded to each other by a first bump BP_1d and may be included in the first bonding chips BS1. The fifth chip CH5d and the sixth chip CH6d may be bonded to each other by a second bump BP_2d, the sixth chip CH6d and the seventh chip CH7d may be bonded to each other by a third bump BP_3d, and may be included in the first bonding chips BS1. The seventh chip CH7d and the eighth chip CH8d may be bonded to each other by a fourth bump BP_4d, and may be included in the first bonding chips BS1.

The eighth chip CH8d may be referred to as a capping semiconductor chip.

In an example, the eighth chip CH8d may be substantially the same as the C-type semiconductor chip CH_C described with reference to FIG. 1B. In another example, the eighth chip CH8d may be a capping semiconductor chip in which the through-electrode structure 42 and the first bonding pad PD_Bb are not provided and the semiconductor substrate 32 may have an increased thickness in the C-type semiconductor chip CH_C.

In an example embodiment, the first chip CH1d, the second chip CH2d, and the third chip CH3d may be the D-type semiconductor chip CH_D described with reference to FIG. 1B. The fourth chip CH4d may be the B-type semiconductor chip CH_B described with reference to FIG. 1A. The fifth chip CH5d, the sixth chip CH6d, and the seventh chip CH7d may be the C-type semiconductor chip CH_C described with reference to FIG. 1B.

Accordingly, the first chip CH1d, the second chip CH2d, the third chip CH3d, the fourth chip CH4d, the fifth chip CH5d, the sixth chip CH6d, the seventh chip CH7d, and the eighth chip CH8d stacked in order may be referred to as the D-type semiconductor chip CH_D, the D-type semiconductor chip CH_D, the D-type semiconductor chip CH_D, the B-type semiconductor chip CH_B, the C-type semiconductor chip CH_C, the C-type semiconductor chip CH_C, the C-type semiconductor chip CH_C, and the capping semiconductor chip CH8d stacked in order. The capping semiconductor chip CH8d may have a structure the same as or similar to that of the C-type semiconductor chip CH_C.

The first bonding chips BS1 bonded to each other by the bump BP may include a first bonding lower chip including a first bonding upper pad PD_Bb in contact with and bonded to the bump BP, and a first bonding upper chip disposed on the first bonding lower chip and including a first bonding lower pad PD_Bf in contact with and bonded to the bump BP.

The directly bonded second bonding chips BS2 may include a second bonding lower chip including a second bonding upper insulating layer IN_Db and a second bonding upper pad PD_Db, and a second bonding upper chip disposed on the second bonding lower chip and including a second bonding lower insulating layer IN_Df in contact with and bonded to the second bonding upper insulating layer IN_Db and a second bonding lower pad PD_Df in contact with and bonded to the second bonding upper pad PD_Db.

Among the fourth chip CH4d and the fifth chip CH5d included in the first bonding chips BS1, the fourth chip CH4d may be the first bonding lower chip, and the fifth chip CH5d may be the first bonding upper chip. Among the fifth chip CH5d and the sixth chip CH6d included in the first bonding chips BS1, the fifth chip CH5d may be the first bonding lower chip, and the sixth chip CH6d may be the first bonding upper chip. Among the sixth chip CH6d and the seventh chip CH7d included in the first bonding chips BS1, the sixth chip CH6d may be the first bonding lower chip, and the seventh chip CH7d may be the first bonding upper chip. Among the seventh chip CH7d and the eighth chip CH8d included in the first bonding chips BS1, the seventh chip CH7d may be the first bonding lower chip, and the eighth chip CH8d may be the first bonding upper chip.

Among the first chip CH1d and the second chip CH2d included in the second bonding chips BS2, the first chip CH1d may be the second bonding lower chip, and the second chip CH2d may be the second bonding upper chip. Among the second chip CH2d and the third chip CH3d included in the second bonding chips BS2, the second chip CH2d may be the second bonding lower chip, and the third chip CH3d may be the second bonding upper chip. Among the third chip CH3d and the fourth chip CH4d included in the second bonding chips BS2, the third chip CH3d may be the second bonding lower chip, and the fourth chip CH4d may be the second bonding upper chip.

The fourth chip CH4d may be the first bonding lower chip among the fourth chip CH4d and the fifth chip CH5d included in the first bonding chips BS1, and may be the second bonding upper chip among the third chip CH3d and the fourth chip CH4d included in the second bonding chips BS2. Accordingly, the fourth chip CH4d may be a shared chip of the first bonding chips BS1 and the second bonding chips BS2.

The adhesive film 50d may surround the side surface of the bump BP, may fill a region between the first bonding lower chip (e.g., CH4d) and the first bonding upper chip (e.g., CH5d), and may extend to side surfaces of the first bonding lower chip and the first bonding upper chip. For example, the adhesive film 50d may include a first adhesive film 50d_1 surrounding a side surface of the first bump BP_1d, filling a region between the fourth chip CH4d and the fifth chip CH5d, and extending to side surfaces of the fourth chip CH4d and the fifth chip CH2d, a second adhesive film 50d_2 surrounding a side surface of the second bump BP_2d, filling a region between the fifth chip CH5d and the sixth chip CH6d and extending to side surfaces of the fifth chip CH5d and the sixth chip CH6d, a third adhesive film 50d_3 surrounding the side surfaces of the third bump BP_3d, filling a region between the sixth chip CH6d and the seventh chip CH7d and extending to side surfaces of the sixth chip CH6d and the seventh chip CH7d, and a fourth adhesive film 50d_4 surrounding a side surface of the fourth bump BP_4d, filling a region between the seventh chip CH7d and the eighth chip CH8d, and extending to side surfaces of the seventh chip CH7d and the eighth chip CH8d.

The first adhesive film 50d_1, the second adhesive film 50d_2, the third adhesive film 50d_3, and the fourth adhesive film 50d4 may be connected to each other.

The first chip CH1d and the lower chip LCd may be lower bonding chips BS2′ directly bonded to each other. For example, similarly to the second bonding chips BS2, the second bonding pad PD_Df and the second bonding insulating layer IN_Df of the first chip CH1d, in other words, the D-type semiconductor chip CH_D, may be directly bonded to the upper pad 19_PD and the upper bonding insulating layer 19_IN of the lower chip LCd.

The mold layer 55d may cover the side surface of the stack chip structure CH_Sd and may cover the adhesive film 50d on the lower chip LCd.

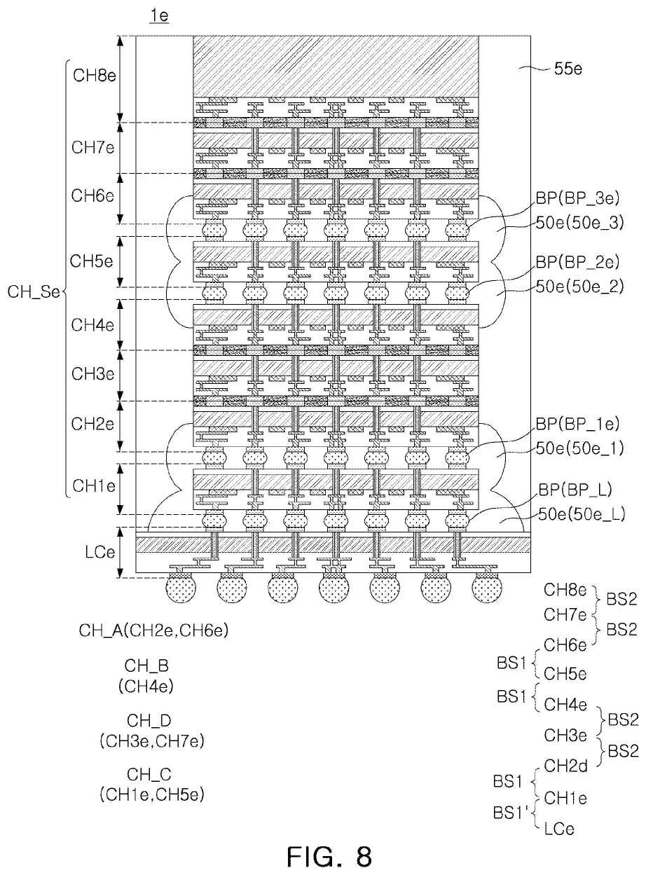

A modified example of a semiconductor package according to an example embodiment will be described with reference to FIG. 8 along with FIGS. 1A and 1B. FIG. 8 is a cross-sectional diagram illustrating a modified example of a semiconductor package according to an example embodiment.

Referring to FIG. 8 together with FIGS. 1A and 1B, the semiconductor package 1e in the modified example may include a lower chip LCe, a stack chip structure CH_Se, an adhesive film 50e, and a mold layer 55e.

The lower chip LCe may be substantially the same as the lower chip LCa in FIGS. 2A to 2C.

The stack chip structure CH_Se may include semiconductor chips BS1 and BS2 stacked in a vertical direction perpendicular to the upper surface of the lower chip LCe. In the stack chip structure CH_Se, the semiconductor chips BS1 stacked in the vertical direction may include a first bonding chips BS1 bonded to each other by a bump BP and a second bonding chips BS2 directly bonded to each other.

In the stack chip structure CH_Se, the number of the plurality of semiconductor chips may be eight or more. A plurality of the first bonding chips BS1 may be provided, and a plurality of the second bonding chips BS2 may be provided. The plurality of semiconductor chips may include a first chip CH1e, a second chip CH2e, a third chip CH3e, a fourth chip CH4e, a fifth chip CH5e, a sixth chip CH6e, a seventh chip CH7e, and an eighth chip CH8e stacked in order in the vertical direction.

The first chip CH1e and the second chip CH2e may be bonded to each other by a first bump BP_1e, and may be included in the first bonding chips BS1. The second chip CH2e and the third chip CH3e may be directly bonded to each other, and may be included in the second bonding chips BS2. The third chip CH3e and the fourth chip CH4e may be directly bonded to each other, and may be included in the second bonding chips BS2. The fourth chip CH4e and the fifth chip CH5e may be bonded to each other by a second bump BP_2e, and may be included in the first bonding chips BS1. The fifth chip CH5e and the sixth chip CH6e may be bonded to each other by a third bump BP_3e and may be included in the first bonding chips BS1. The sixth chip CH6e and the seventh chip CH7e may be directly bonded to each other, and may be included in the second bonding chips BS2. The seventh chip CH7e and the eighth chip CH8e may be directly bonded to each other and may be included in the second bonding chips BS2.

The eighth chip CH8e may be referred to as a capping semiconductor chip.

In an example, the eighth chip CH8e may be substantially the same as the D-type semiconductor chip CH_D described with reference to FIG. 1B. In another example, the eighth chip CH8e may be a capping semiconductor chip in which the through-electrode structure 42, the second bonding pad PD_Db, and the second bonding insulating layer IN_Db are not provided and the semiconductor substrate 32 may have an increased thickness in the D-type semiconductor chip CH_D.

In an example embodiment, the first chip CH1e and the fifth chip CH5e may be the C-type semiconductor chip CH_C described with reference to FIG. 1B. The third chip CH3e and the seventh chip CH7e may be the D-type semiconductor chip CH_D described with reference to FIG. 1B. The second chip CH2e and the sixth chip CH6e may be the A-type semiconductor chip CH_A described with reference to FIG. 1A. The fourth chip CH4e may be the B-type semiconductor chip CH_B described with reference to FIG. 1A.

Accordingly, the first chip CH1e, the second chip CH2e, the third chip CH3e, the fourth chip CH4e, the fifth chip CH5e, the sixth chip CH6e, the seventh chip CH7e, and the eighth chip CH8e stacked in order may be referred to as the C-type semiconductor chip CH_C, the A-type semiconductor chip CH_A, the D-type semiconductor chip CH_D, the B-type semiconductor chip CH_B, the C-type semiconductor chip CH_C, the A-type semiconductor chip CH_A, the D-type semiconductor chip CH_D, and the capping semiconductor chip CH8e stacked in order. The capping semiconductor chip CH8e may have a structure the same as or similar to that of the D-type semiconductor chip CH_D.

The first bonding chips BS1 bonded to each other by the bump BP may include a first bonding lower chip including a first bonding upper pad PD_Bb in contact with and bonded to the bump BP, and a first bonding upper chip disposed on the first bonding lower chip and including a first bonding lower pad PD_Bf in contact with and bonded to the bump BP.

The directly bonded second bonding chips BS2 may include a second bonding lower chip including a second bonding upper insulating layer IN_Db and a second bonding upper pad PD_Db, and a second bonding upper chip disposed on the second bonding lower chip, and including a second bonding lower insulating layer IN_Df in contact with and bonded to the second bonding upper insulating layer IN_Db and a second bonding upper pad PD_Db in contact with and bonded to the second bonding upper pad PD_Db.

Among the first chip CH1e and the second chip CH2e included in the first bonding chips BS1, the first chip CH1e may be the first bonding lower chip, and, the second chip CH2e may be the first bonding upper chip. Among the fourth chip CH4e and the fifth chip CH5e included in the first bonding chips BS1, the fourth chip CH4e may be the first bonding lower chip, and the fifth chip CH5e may be the first bonding upper chip. Among the fifth chip CH5e and the sixth chip CH6e included in the first bonding chips BS1, the fifth chip CH5e may be the first bonding lower chip, and sixth chip CH6e may be the first bonding upper chip.

Among the second chip CH2e and the third chip CH3e included in the second bonding chips BS2, the second chip CH2e may be the second bonding lower chip, and the third chip CH3e may be the second bonding upper chip. Among the third chip CH3e and the fourth chip CH4e included in the second bonding chips BS2, the third chip CH3e may be the second bonding lower chip, and the fourth chip CH4e may be the second bonding upper chip. Among the sixth chip CH6e and the seventh chip CH7e included in the second bonding chips BS2, the sixth chip CH6e may be the second bonding lower chip, and the seventh chip CH7e may be the second bonding upper chip. Among the seventh chip CH7e and the eighth chip CH8e included in the second bonding chips BS2, the seventh chip CH7e may be the second bonding lower chip, and the eighth chip CH8e may be the second bonding upper chip.

The second chip CH2e may be the first bonding upper chip among the first chip CH1e and the second chip CH2e included in the first bonding chips BS1, and may be the second bonding lower chip among the second chip CH2e and the third chip CH3e included in the second bonding chips BS2. Accordingly, the second chip CH2e may be a shared chip of the first bonding chips BS1 and the second bonding chips BS2. Similarly, each of the fourth chip CH4e and the sixth chip CH6e may be a shared chip of the first bonding chips BS1 and the second bonding chips BS2.

The adhesive film 50e may surround the side surface of the bump BP, may fill a region between the first bonding lower chip (e.g., CH4e) and the first bonding upper chip (e.g., CH5e), and may extend to side surfaces of the first bonding lower chip and the first bonding upper chip. For example, the adhesive film 50d may include a first adhesive film 50e_1 surrounding a side surface of the first bump BP_1e, filling a region between the first chip CH1e and the second chip CH2e, and extending to side surfaces of the first chip CH1e and the second chip CH2e, a second adhesive film 50e_2 surrounding a side surface of the second bump BP_2e, filling a region between the fourth chip CH4e and the fifth chip CH5e and extending to side surfaces of the fourth chip CH4e and the fifth chip CH5e, and a third adhesive film 50e_3 surrounding a side surface of the third bump BP_3e, filling a region between the fifth chip CH5e and the sixth chip CH6e and extending to side surfaces of the fifth chip CH5e and the sixth chip CH6e.

The second adhesive film 50e_2 and the third adhesive film 50e_3 may be connected to each other, and may be spaced apart from the first adhesive film 50e_1. For example, the third chip CH3e may be disposed between the second adhesive film 50e_2 and the first adhesive film 50e_1.

The first chip CH1e and the lower chip LCe may be bonded to each other by a lower bump BP_L. Accordingly, the first chip CH1e and the lower chip LCe may be lower bonding chips BS1′ bonded to each other by the lower bump BP_L, similarly to the first bonding chips BS1.

The adhesive film 50e may further include a lower adhesive film 50e_L surrounding the side surface of the lower bump BP_L, filling a region between the first chip CH1e and the lower chip LCe, and extending to the side surface of the first chip CH1e.

The lower adhesive film 50e_L and the first adhesive film 50e_1 may be connected to each other.

The mold layer 55e may cover the side surface of the stack chip structure CH_Se and may cover the adhesive film 50e on the lower chip LCe.

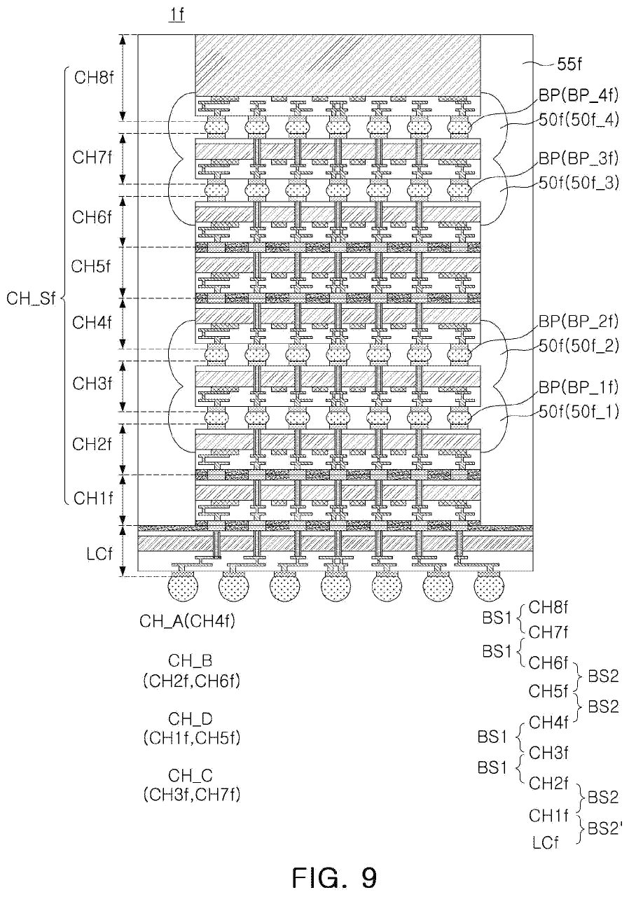

A modified example of a semiconductor package according to an example embodiment will be described with reference to FIG. 9 along with FIGS. 1A and 1B. FIG. 9 is a cross-sectional diagram illustrating a modified example of a semiconductor package according to an example embodiment.

Referring to FIG. 9 together with FIGS. 1A and 1B, the semiconductor package if in the modified example may include a lower chip LCf, a stack chip structure CH_Sf, an adhesive film 50f and a mold layer 55f.

The lower chip LCf may be substantially the same as the lower chip LCb in FIG. 4.

The stack chip structure CH_Sf may include semiconductor chips BS1 and BS2 stacked in a vertical direction perpendicular to the upper surface of the lower chip LCf. In the stack chip structure CH_Sf, the semiconductor chips BS1 stacked in the vertical direction may include first bonding chips BS1 bonded to each other by bumps BP and second bonding chips BS2 directly bonded to each other.

In the stack chip structure CH_Sf, the number of the plurality of semiconductor chips may be eight or more. A plurality of the first bonding chips BS1 may be provided, and a plurality of the second bonding chips BS2 may be provided. The plurality of semiconductor chips may include a first chip CH1f, a second chip CH2f, a third chip CH3f, a fourth chip CH4f, a fifth chip CH5f, a sixth chip CH6f, a seventh chip CH7f, and an eighth chip CH8f stacked in order in the vertical direction.

The first chip CH1f and the second chip CH2f may be directly bonded to each other and may be included in the second bonding chips BS2, and the second chip CH2f and the third chip CH3f may be directly bonded to each other by the first bump BP_1f, and may be included in the first bonding chips BS1. The third chip CH3f and the fourth chip CH4f may be bonded to each other by the second bumps BP_2f and may be included in the first bonding chips BS1. The fourth chip CH4f and the fifth chip CH5f may be directly bonded to each other, and may be included in the second bonding chips BS2. The fifth chip CH5f and the sixth chip CH6f may be directly bonded to each other and may be included in the second bonding chips BS2. The sixth chip CH6f and the seventh chip CH7f may be bonded to each other by the third bump BP_3f, and may be included in the first bonding chips BS1. The seventh chip CH7f and the eighth chip CH8f may be bonded to each other by the fourth bumps BP_4f, and may be included in the first bonding chips BS1.

The eighth chip CH8f may be referred to as a capping semiconductor chip.

In an example, the eighth chip CH8f may be substantially the same as the C-type semiconductor chip CH_C described with reference to FIG. 1B. In another example, the eighth chip CH8f may be a capping semiconductor chip in which the through-electrode structure 42 and the first bonding pad PD_Bb are not provided, and the semiconductor substrate 32 may have an increased thickness in the C-type semiconductor chip CH_C.

In an example embodiment, the first chip CH1f and the fifth chip CH5f may be the D-type semiconductor chip CH_D described with reference to FIG. 1B. The third chip CH3f and the seventh chip CH7f may be the C-type semiconductor chip CH_C described with reference to FIG. 1B. The second chip CH2f and the sixth chip CH6f may be the B-type semiconductor chip CH_B described with reference to FIG. 1A. The fourth chip CH4f may be the A-type semiconductor chip CH_A described with reference to FIG. 1A.

Accordingly, the first chip CH1f, the second chip CH2f, the third chip CH3f, the fourth chip CH4f, the fifth chip CH5f, the sixth chip CH6f, the seventh chip CH7f, and the eighth chip CH8f stacked in order may be referred to as the D-type semiconductor chip CH_D, the B-type semiconductor chip CH_B, the C-type semiconductor chip CH_C, the A-type semiconductor chip CH_A, the D-type semiconductor chip (CH_D), the B-type semiconductor chip CH_B, the C-type semiconductor chip CH_C, and the capping semiconductor chip CH8f. The capping semiconductor chip CH8f may have a structure the same as or similar to that of the C-type semiconductor chip CH_C.

The first bonding chips BS1 bonded to each other by the bump BP may include a first bonding lower chip including a first bonding upper pad PD_Bb in contact with and bonded to the bump BP, and a first bonding upper chip disposed on the first bonding lower chip and including a first bonding lower pad PD_Bf in contact with and bonded to the bump BP.

The directly bonded second bonding chips BS2 may include a second bonding lower chip including a second bonding upper insulating layer IN_Db and a second bonding upper pad PD_Db, and a second bonding upper chip disposed on the second bonding lower chip and including a second bonding lower insulating layer IN_Df in contact with and bonded to the second bonding upper insulating layer IN_Db and a second bonding lower pad PD_Df in contact with and bonded to the second bonding upper pad PD_Db.

Among the second chip CH2f and the third chip CH3f included in the first bonding chips BS1, the second chip CH2f may be the first bonding lower chip, and the third chip CH3f may be the first bonding upper chip. Among the third chip CH3f and the fourth chip CH3f included in the first bonding chips BS1, the third chip CH3f may be the first bonding lower chip, and the fourth chip CH4f may be the first bonding upper chip. Among the sixth chip CH6f and the seventh chip CH7f included in the first bonding chips BS1, the sixth chip CH6f may be the first bonding lower chip, and the seventh chip CH7f may be the first bonding upper chip. Among the seventh chip CH7f and the eighth chip CH8f included in the first bonding chips BS1, the seventh chip CH7f may be the first bonding lower chip, and the eighth chip CH8f may be the first bonding upper chip.

Among the first chip CH1f and the second chip CH2f included in the second bonding chips BS2, the first chip CH1f may be the second bonding lower chip, and the second chip CH2f may be the second bonding upper chip. Among the fourth chip CH4f and the fifth chip CH5f included in the second bonding chips BS2, the fourth chip CH4f may be the second bonding lower chip, and the fifth chip CH5f may be the second bonding upper chip. Among the fifth chip CH5f and the sixth chip CH6f included in the second bonding chips BS2, the fifth chip CH5f may be the second bonding lower chip, and the sixth chip CH6f may be the second bonding upper chip.

The second chip CH2f may be the first bonding upper chip among the first chip CH1f and the second chip CH2f included in the second bonding chips BS2, and may be the second bonding lower chip among the second chip CH2f and the third chip CH3f included in the first bonding chips BS1. Accordingly, the second chip CH2f may be a shared chip of the first bonding chips BS1 and the second bonding chips BS2. Similarly, each of the fourth chip CH4f and the sixth chip CH6f may be a shared chip of the first bonding chips BS1 and the second bonding chips BS2.

The adhesive film 50f may surround the side surface of the bump BP, may fill a region between the first bonding lower chip and the first bonding upper chip, and may extend to side surfaces of the first bonding lower chip and the first bonding upper chip. For example, the adhesive film 50d may include a first adhesive film 50f_1 surrounding a side surface of the first bump BP_1f, filling a region between the second chip CH2f and the third chip CH3f, and extending to side surfaces of the second chip CH2f and the third chip CH3f, a second adhesive film 50f_2 surrounding a side surface of the second bump BP_2f, filling a region between the third chip CH3f and the fourth chip CH4f and extending to side surfaces of the third chip CH3f and the fourth chip CH4f, a third adhesive film 50f_3 surrounding the side surface of the third bump BP_3f, filling a region between the sixth chip CH6f and the seventh chip CH7f and extending to side surfaces of the sixth chip CH6f and the seventh chip CH7f, and a fourth adhesive film 50f_4 surrounding a side surface of the fourth bump BP_4f, filling a region between the seventh chip CH7f and the eighth chip CH8f and extending to side surfaces of the seventh chip CH7f and the eighth chip CH8f. The first adhesive film 50f_1 and the second adhesive film 50f_2 may be connected to each other, and the third adhesive film 50f_3 and the fourth adhesive film 50f_4 may be connected to each other. The first adhesive film 50f_1 and the second adhesive film 50f_2 may be spaced apart from the third adhesive film 50f_3 and the fourth adhesive film 50f_4. For example, the fifth chip CH5f may be disposed between the second adhesive film 50f_2 and the third adhesive film 50f_3.

The first chip CH1f and the lower chip LCf may be lower bonding chips BS2′ directly bonded to each other. For example, similarly to the second bonding chips BS2, the second bonding pad PD_Df and the second bonding insulating layer IN_Df of the first chip CH1f, in other words, the D-type semiconductor chip CH_D, may be directly bonded to the upper pad 19_PD and the upper bonding insulating layer 19_IN of the lower chip LCf.

The mold layer 55f may cover the side surface of the stack chip structure CH_Sf and may cover the adhesive film 50f on the lower chip LCf.

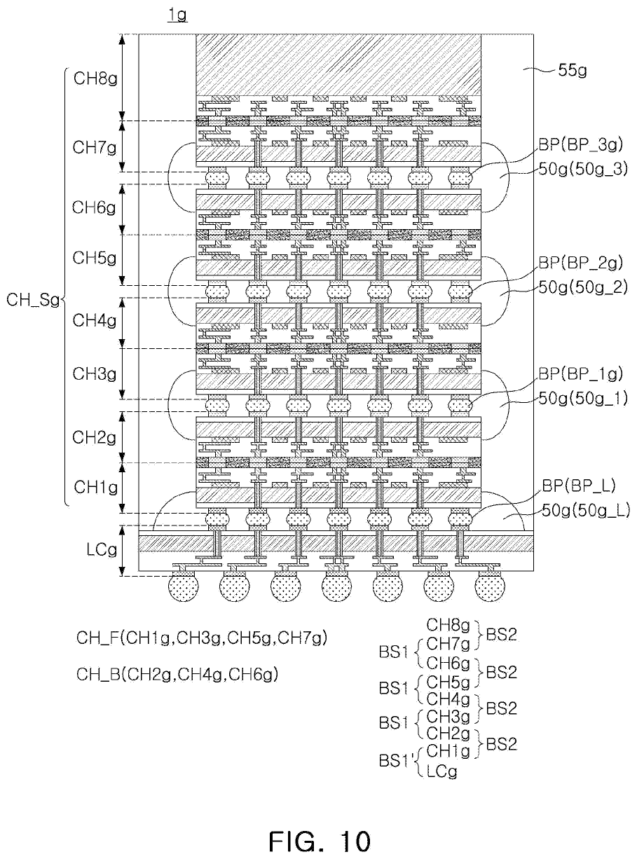

A modified example of a semiconductor package according to an example embodiment will be described with reference to FIG. 10 along with FIGS. 1A and 1C. FIG. 10 is a cross-sectional diagram illustrating a modified example of a semiconductor package according to an example embodiment.

Referring to FIG. 10 together with FIGS. 1A and 1C, a semiconductor package Ig according to an example embodiment may include a lower chip LCg, a stack chip structure CH_Sg, an adhesive film 50g and a mold layer 55.

The lower chip LCg may be substantially the same as the lower chip LCa in FIGS. 2A to 2C.

The stack chip structure CH_Sg may include semiconductor chips BS1 and BS2 stacked in a vertical direction perpendicular to the upper surface of the lower chip LCg.

The semiconductor chips BS1 stacked in the vertical direction may include first bonding chips BS1 bonded to each other by bumps BP and second bonding chips BS2 directly bonded to each other.

The first bonding chips BS1 bonded to each other by the bump BP may include a first bonding lower chip CH_B including a first bonding upper pad PD_Bb in contact with and bonded to the bump BP, and a first bonding upper chip CH_F disposed on the first bonding lower chip CH_B, and including a first bonding lower pad PD_Bf in contact with and bonded to the bump BP.

The adhesive film 50g may surround the side surface of the bump BP, may fill a region between the first bonding lower chip CH_B and the first bonding upper chip CH_F, and may extend to side surfaces of the first bonding lower chip CH_B and the first bonding upper chip CH_F.

The directly bonded second bonding chips BS2 may include a second bonding lower chip CH_F including a second bonding upper insulating layer IN_Db and a second bonding upper pad PD_Db, and a second bonding upper chip CH_B including a second bonding lower insulating layer IN_Df in contact with and bonded to the second bonding upper insulating layer IN_Db, and a second bonding lower pad PD_Df in contact with and bonded to the second bonding upper pad PD_Db.

In the first bonding chips BS1, the first bonding upper chip CH_F may be the F-type semiconductor chip described with reference to FIG. 1C, and the first bonding lower chip CH_B may be the B-type semiconductor chip described with reference to FIG. 1A. In the second bonding chips BS2, the second bonding upper chip CH_B may be the B-type semiconductor chip described with reference to FIG. 1A, and the second bonding lower chip CH_F may be the F-type semiconductor chip described with reference to FIG. 1C. Accordingly, the stack chip structure CH_Sg may include the F-type semiconductor chip CH_F, the B-type semiconductor chip CH_B, the F-type semiconductor chip CH_F, and the B-type semiconductor chip CH_B stacked in order and bonded to each other.

In the stack chip structure CH_Sg, the number of the plurality of semiconductor chips may be eight or more. A plurality of the first bonding chips may be provided, and a plurality of the second bonding chips may be provided. The plurality of semiconductor chips may include a first chip CH1g, a second chip CH2g, a third chip CH3g, a fourth chip CH4g, a fifth chip CH5g, a sixth chip CH6g, a seventh chip CH7g, and an eighth chip CH8g stacked in order in the vertical direction.

The first chip CH1g and the second chip CH2g may be directly bonded to each other and may be included in the second bonding chips BS2, and the second chip CH2g and the third chip CH3g may be bonded to each other by the first bump BP_1g, may be included in the first bonding chips BS1. The third chip CH3g and the fourth chip CH4g may be directly bonded to each other, and may be included in the second bonding chips BS2. The fourth chip CH4g and the fifth chip CH5g may be bonded to each other by a second bump BP_2g, and may be included in the first bonding chips BS1. The fifth chip CH5g and the sixth chip CH6g may be directly bonded to each other, and may be included in the second bonding chips BS2. The sixth chip CH6g and the seventh chip CH7g may be bonded to each other by the third bump BP_3g, and may be included in the first bonding chips BS1. The seventh chip CH7g and the eighth chip CH8g may be directly bonded to each other and may be included in the second bonding chips BS2.

The eighth chip CH8g may be referred to as a capping semiconductor chip.

In an example, the eighth chip CH8g may be substantially the same as the B-type semiconductor chip CH_B. In another example, the eighth chip CH8g may be a capping semiconductor chip in which the through-electrode structure 42 and the first bonding pad PD_Bb are not provided, and the semiconductor substrate 32 may have an increased thickness in the B-type semiconductor chip CH_B.

The first chip CH1g, the third chip CH3g, the fifth chip CH5g, and the seventh chip CH7g may be the F-type semiconductor chip CH_F described with reference to FIG. 1C, and the second chip CH2g, the fourth chip CH4g, and the sixth chip CH6g may be the B-type semiconductor chip CH_B described with reference to FIG. 1A.

Among the second chip CH2g and the third chip CH3g included in the first bonding chips BS1, the second chip CH2g may be the first bonding lower chip, and the third chip CH3g may be the first bonding upper chip. Among the fourth chip CH4g and the fifth chip CH5g included in the first bonding chips BS1, the fourth chip CH4g may be the first bonding lower chip, and the fifth chip CH5g may be the first bonding upper chip. Among the sixth chip CH6g and the seventh chip CH7g included in the first bonding chips BS1, the sixth chip CH6g may be the first bonding lower chip, and the seventh chip CH7g may be the first bonding upper chip.

Among the first chip CH1g and the second chip CH2g included in the second bonding chips BS2, the first chip CH1g may be the second bonding lower chip, and the second chip CH2g may be the second bonding upper chip. Among the third chip CH3g and the fourth chip CH4g included in the second bonding chips BS2, the third chip CH3g may be the second bonding lower chip, and the fourth chip CH4g may be the second bonding upper chip. Among the fifth chip CH5g and the sixth chip CH6g included in the second bonding chips BS2, the fifth chip CH5g may be the second bonding lower chip, and the sixth chip CH6g may be the second bonding upper chip. Among the seventh chip CH7g and the eighth chip CH8g included in the second bonding chips BS2, the seventh chip CH7g may be the second bonding lower chip, and the eighth chip CH8g may be the second bonding upper chip.

The second chip CH2g may be the second bonding upper chip among the first chip CH1g and the second chip CH2g included in the second bonding chips BS2, and may be the first bonding lower chip among the second chip CH2g and the third chip CH3g included in the first bonding chips BS1. Accordingly, since the second chip CH2g may be the second bonding upper chip and the first bonding lower chip, the second chip CH2g may be a shared chip of the first bonding chips BS1 and the second bonding chips BS2. Similarly, the third chip CH3g, the fourth chip CH4g, the fifth chip CH5g, the sixth chip CH6g, and the seventh chip CH7g may be a shared chip of the first bonding chips BS1 and the second bonding chips BS2.

The adhesive film 50g may include a first adhesive film 50g_1 surrounding a side surface of the first bump BP_1g, filling a region between the second chip CH2g and the third chip CH3g, and extending to side surfaces of the second chip CH2g and the third chip CH3g, a second adhesive film 50g_2 surrounding the side surface of the second bump BP_2g, filling a region between the fourth chip CH4g and the fifth chip CH5g, and extending to side surfaces of the fourth chip CH4g and the fifth chip CH5g and a third adhesive film 50g_3 surrounding the side surface of the third bump BP_3g, filling a region between the sixth chip CH6g and the seventh chip CH7g and extending to side surfaces of the sixth chip CH6g and the seventh chip CH7g.

In an example, the first adhesive film 50g_1, the second adhesive film 50g_2, and the third adhesive film 50g_3 may be spaced apart from each other in the vertical direction. In another example, the first adhesive film 50g_1, the second adhesive film 50g_2, and the third adhesive film 50g_3 may be connected to each other.

The first chip CH1g and the lower chip LCg may be bonded to each other by a lower bump BP_L. Accordingly, the first chip CH1g and the lower chip LCg may be lower bonding chips BS1′ bonded to each other by the lower bump BP_L, similarly to the first bonding chips BS1. The adhesive film 50g may further include a lower adhesive film 50g_L surrounding the side surface of the lower bump BP_L, filling a region between the first chip CH1g and the lower chip LCg, and extending to a side surface of the first chip CH1g. The mold layer 55g may cover the side surface of the stack chip structure CH_Sg and may the adhesive film 50g on the lower chip LCg.

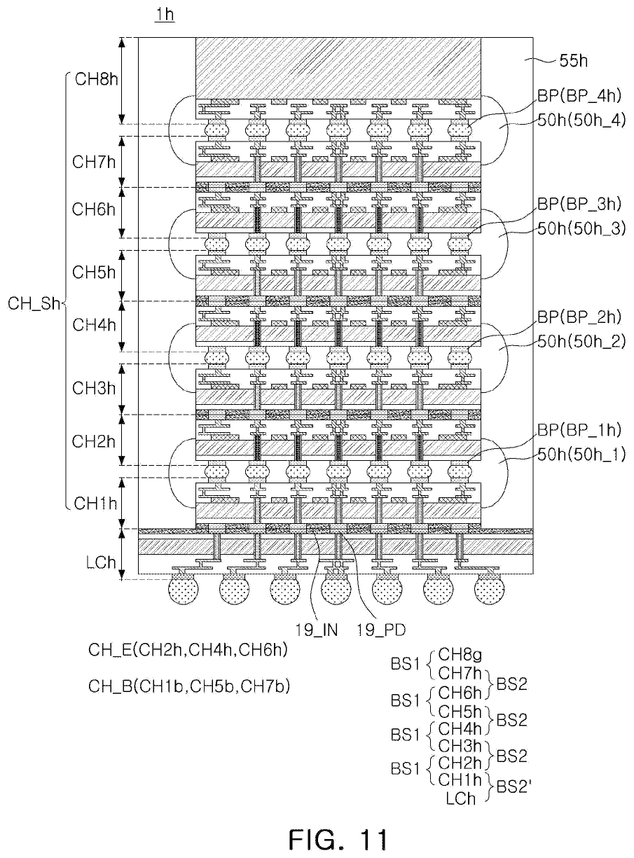

A modified example of a semiconductor package according to an example embodiment will be described with reference to FIG. 11 along with FIGS. 1A and 1C. FIG. 11 is a cross-sectional diagram illustrating a modified example of a semiconductor package according to an example embodiment.

In the modified example, referring to FIG. 11 together with FIGS. 1A and 1C, the semiconductor package 1h in the modified example may include a lower chip LCh, a stack chip structure CH_Sh, an adhesive film 50h and a mold layer 55h.

The lower chip LCh may be substantially the same as the lower chip LCb described with reference to FIG. 4.

The stack chip structure CH_Sh may include semiconductor chips BS1 and BS2 stacked in a vertical direction perpendicular to the upper surface of the lower chip LCh.

In the stack chip structure CH_Sh, the vertically stacked semiconductor chips BS1 and BS2 may include a first bonding chips BS1 bonded to each other by a bump BP and second bonding chips BS2 directly bonded to each other.

The first bonding chips BS1 bonded to each other by the bump BP may include a first bonding lower chip CH_E including a first bonding upper pad PD_Bb in contact with and bonded to the bump BP, and a first bonding upper chip CH_B disposed on the first bonding lower chip CH_E and including a first bonding lower pad PD_Bf in contact with and bonded to the bump BP.

The adhesive film 50h may surround the side surface of the bump BP, may fill a region between the first bonding lower chip CH_B and the first bonding upper chip CH_F, and may extend to side surfaces of the first bonding lower chip CH_B and the first bonding upper chip CH_F.

The directly bonded second bonding chips BS2 may include a second bonding lower chip CH_B including a second bonding upper insulating layer IN_Db and a second bonding upper pad PD_Db, and a second bonding upper chip CH_E disposed on the bonding lower chip CH_B and including a second bonding lower insulating layer IN_Df in contact with and bonded to the second bonding upper insulating layer IN_Db, and a second bonding lower pad PD_Df in contact with and bonded to the second bonding upper pad PD_Db.

In the first bonding chips BS1, the first bonding upper chip CH_B may be the B-type semiconductor chip described with reference to FIG. 1A, and the first bonding lower chip CH_E may be the E-type semiconductor chip described with reference to FIG. 1C. In the second bonding chips BS2, the second bonding upper chip CH_E may be the E-type semiconductor chip described with reference to FIG. 1C, and the second bonding lower chip CH_B may be the B-type semiconductor chip described with reference to FIG. 1A.

The stack chip structure CH_Sh may include the E-type semiconductor chip CH_E, the B-type semiconductor chip CH_B, the E-type semiconductor chip CH_E, and the B-type semiconductor chip CH_B stacked in order and bonded to each other.

In the stack chip structure CH_Sh, the number of the plurality of semiconductor chips may be eight or more. A plurality of the first bonding chips may be provided, and a plurality of the second bonding chips may be provided. The plurality of semiconductor chips may include a first chip CH1h, a second chip CH2h, a third chip CH3h, a fourth chip CH4h, a fifth chip CH5h, a sixth chip CH6h, a seventh chip CH7h, and an eighth chip CH8h stacked in order in the vertical direction.

The first chip CH1h and the second chip CH2h may be bonded to each other by a first bump BP_1h and may be included in the first bonding chips BS1. The second chip CH2h and the third chip CH3h may be directly bonded to each other and may be included in the second bonding chips BS2. The third chip CH3h and the fourth chip CH4h may be bonded to each other by a second bump BP_2h and may be included in the first bonding chips BS1. The fourth chip CH4h and the fifth chip CH5h may be directly bonded to each other, and may be included in the second bonding chips BS2. The fifth chip CH5h and the sixth chip CH6h may be bonded to each other by a third bump BP_3h, and may be included in the first bonding chips BS1. The sixth chip CH6h and the seventh chip CH7h may be directly bonded to each other, and may be included in the second bonding chips BS2. The seventh chip CH7h and the eighth chip CH8h may be bonded to each other by a fourth bump BP_4h, and may be included in the first bonding chips BS1.

The eighth chip CH8h may be referred to as a capping semiconductor chip.

In an example, the eighth chip CH8h may be substantially the same as the B-type semiconductor chip CH_B. In another example, the eighth chip CH8h may be a capping semiconductor chip in which the through-electrode structure 42, the second bonding pad PD_Db, and the second bonding insulating layer IN_Db are not provided, and the semiconductor substrate 32 may have an increased thickness in the B-type semiconductor chip CH_B.

The first chip CH1h, the third chip CH3h, the fifth chip CH5h, and the seventh chip CH7h may be the E-type semiconductor chip CH_E described with reference to FIG. 1C, and the second chip CH2h, the fourth chip CH4h, and the sixth chip CH6h may be the B-type semiconductor chip CH_B described with reference to FIG. 1A.

Among the first chip CH1h and the second chip CH2h included in the first bonding chips BS1, the first chip CH1h may be the first bonding lower chip, and, the second chip CH2h may be the first bonding upper chip. Among the third chip CH3h and the fourth chip CH4h included in the first bonding chips BS1, the third chip CH3h may be the first bonding lower chip, and the fourth chip CH4h may be the first bonding upper chip. Among the fifth chip CH5h and the sixth chip CH6h included in the first bonding chips BS1, the fifth chip CH5h may be the first bonding lower chip, and the sixth chip CH6h may be the first bonding upper chip. Among the seventh chip CH7h and the eighth chip CH7h included in the first bonding chips BS1, the seventh chip CH7h may be the first bonding lower chip, and the eighth chip CH8h may be the first bonding upper chip.

Among the second chip CH2h and the third chip CH3h included in the second bonding chips BS2, the second chip CH2h may be the second bonding lower chip, and the third chip CH3h may be the second bonding upper chip. Among the fourth chip CH4h and the fifth chip CH5h included in the second bonding chips BS2, the fourth chip CH4h may be the second bonding lower chip, and the fifth chip CH5h may be the second bonding upper chip. Among the sixth chip CH6h and the seventh chip CH7h included in the second bonding chips BS2, the sixth chip CH6h may be the second bonding lower chip, and the seventh chip CH7h may be the second bonding upper chip.

The second chip CH2h may be the first bonding upper chip among the first chip CH1h and the second chip CH2h included in the first bonding chips BS1, and may be the second bonding lower chip among the second chip CH2h and the third chip CH3h included in the second bonding chips BS2. Accordingly, since the second chip CH2h may be the first bonding upper chip and the second bonding lower chip, the second chip CH2h may be a shared chip of the first bonding chips BS1 and the second bonding chips BS2. Similarly, the third chip CH3h, the fourth chip CH4h, the fifth chip CH5h, the sixth chip CH6h, and the seventh chip CH7h may be a shared chip of the first bonding chips BS1 and the second bonding chips BS2.

The adhesive film 50h may include a first adhesive film 50h_1 surrounding a side surface of the first bump BP_1h, filling a region between the first chip CH1h and the second chip CH2h, and extending to the side surfaces of the first chip CH1h and the second chip CH2h, a second adhesive film 50h_2 surrounding the side surface of the second bump BP_2h, filling a region between the third chip CH3h and the fourth chip CH4h, and extending to side surfaces of the third chip CH3h and the fourth chip CH4h, a third adhesive film 50h_3 surrounding the side surface of the third bump BP_3h, filing a region between the fifth chip CH5h and the sixth chip CH6h, and extending to side surfaces of the fifth chip CH5h and the sixth chip CH6h, and a fourth adhesive film 50h_4 surrounding a side surface of the fourth bump BP_4h, filing a region between the seventh chip CH7h and the eighth chip CH8h, and extending to the side surfaces of the seventh chip CH7h and the eighth chip CH8h.

In an example, the first adhesive film 50h_1, the second adhesive film 50h_2, the third adhesive film 50h_3, and the fourth adhesive film 50h_4 may be spaced apart from each other in the vertical direction. In another example, the first adhesive film 50h_1, the second adhesive film 50h_2, the third adhesive film 50h_3, and the fourth adhesive film 50h_4 may be connected to each other.

The first chip CH1h and the lower chip LCh may be lower bonding chips BS2′ directly bonded to each other. For example, similarly to the second bonding chips BS2, the second bonding pad PD_Df and the second bonding insulating layer IN_Df of the first chip CH1h, in other words, the E-type semiconductor chip CH_E, may be directly bonded to the upper pad 19_PD and the upper bonding insulating layer 19_IN of the lower chip LCh.

The mold layer 55h may cover the side surface of the stack chip structure CH_Sh and may cover the adhesive film 50h on the lower chip LCh.

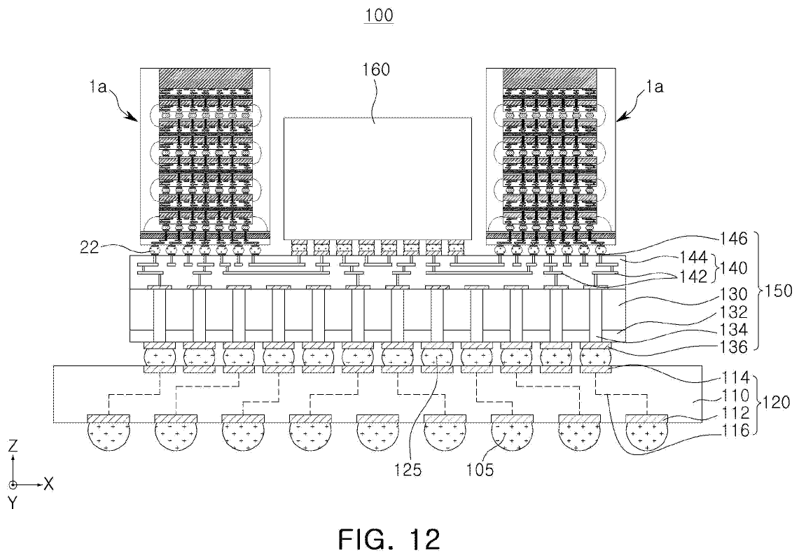

In the description below, an example embodiment of the semiconductor package 100 including one of the semiconductor packages 1a, 1b, 1c, 1d, 1e, 1f, 1g, and 1h described with reference to FIGS. 2A to 11 will be described with reference to FIG. 12. FIG. 12 is a cross-sectional diagram illustrating an example embodiment of the semiconductor package 100 including one of the semiconductor packages 1a, 1b, 1c, 1d, 1e, 1f, 1g, and 1h described with reference to FIGS. 2A to 11.

Referring to FIG. 12, a semiconductor package 100 according to an example embodiment may include a package substrate 120, an interposer 150, and a semiconductor package 1a mounted on the interposer 150 and a semiconductor chip 160. In FIG. 12, the semiconductor package 1a described with reference to FIGS. 2A to 2C is illustrated as the semiconductor package 1a, but an example embodiment thereof is not limited thereto. For example, the semiconductor package 1a may be replaced with one of the semiconductor packages 1b, 1c, 1d, 1e, 1f, 1g, and 1h described with reference to FIGS. 3 to 11. The semiconductor chip 160 may be implemented as a logic chip or a processor chip.

The package substrate 120 may be a substrate for a semiconductor package including a printed circuit board (PCB), a ceramic substrate, a glass substrate, a tape interconnection board, and the like. The package substrate 120 may include a body 110, a lower pad 112 disposed on a lower surface of the body 110, an upper pad 114 disposed on an upper surface of the body 110, and an interconnection circuit 116 electrically connecting the lower pad 112 to the upper pad 114 in the body 110.

The body 110 of the package substrate 120 may include different materials depending on the type of the substrate. For example, when the package substrate 120 is a printed circuit board, the body 110 may have a form in which an interconnection layer is additionally stacked on one surface or both sides of a body or a copper clad laminate.

The lower pad 112, the upper pad 114, and the interconnection circuit 116 may form in an electrical path (e.g., signal path). An external connection bump 105 connected to the lower pad 112 may be disposed below the lower surface of the package substrate 120. The external connection bump 105 may include, for example, a solder ball.

The interposer 150 may include a substrate 130, a lower protective layer 132, a lower pad 136, an interconnection structure 140, and a through via 134. The semiconductor package 1a and the semiconductor chip 160 may be stacked on the package substrate 120 via the interposer 150.

The interposer 150 may electrically connect the semiconductor package 1a and the semiconductor chip 160 to each other. For example, a portion of the interconnection structure 140 of the interposer 150 may provide a signal path through which the semiconductor package 1a and the semiconductor chip 160 may communicate with each other or may be electrically connected to each other.

The substrate 130 may be formed of, for example, one of silicon, an organic material, a plastic, and a glass substrate. When the substrate 130 is a silicon substrate, the interposer substrate 130 may be referred to as a silicon interposer. Differently from that shown in FIG. 12, when the substrate 130 is an organic substrate, the substrate 130 may be referred to as a panel interposer.

The lower protective layer 132 may be disposed below the lower surface of the substrate 130, and the lower pad 136 may be disposed below the lower protective layer 132. The lower pad 136 may be connected to the through via 134.

The interposer 150 may be electrically connected to the package substrate 120 through conductive bumps 125 disposed below the lower pad 136.

The interconnection structure 140 may be disposed on the substrate 130 and may include an interlayer insulating layer 144 and a single-layer or multilayer interconnection structure 142. When the interconnection structure 140 has a multilayer interconnection structure, interconnection patterns of other layers may be connected to each other through contact vias. An upper pad 146 electrically connected to the single-layer or multilayer interconnection structure 142 may be disposed on the interconnection structure 140. The semiconductor package 1a and the semiconductor chip 160 may be electrically connected to the upper pad 146 through a connection bump 22.

The through via 134 may penetrate through the substrate 130. The through via 134 may extend into the interconnection structure 140, and may be electrically connected to the single-layer or multilayer interconnection structure 142 of the interconnection structure 140. When the substrate 130 is silicon, the through via 134 may be referred to as a through silicon via (TSV). In example embodiments, the interposer 150 may be a redistribution interposer not including a through-via instead of a silicon interposer including the through-via 134.

The interposer 150 may be used for converting or transferring an input electrical signal between the package substrate 120, the semiconductor package 1a, and the semiconductor chip 160.

The semiconductor chip 160 may include, for example, a central processor (CPU), a graphics processor (GPU), a field programmable gate array (FPGA), a digital signal processor (DSP), a cryptographic processor, a microprocessor, a microprocessor controller, an analog-to-digital converter, and an application specific integrated circuit (ASIC). Depending on the types of devices included in the semiconductor chip 160, the semiconductor package 100 may be referred to as a server-oriented semiconductor package or a mobile-oriented semiconductor package.

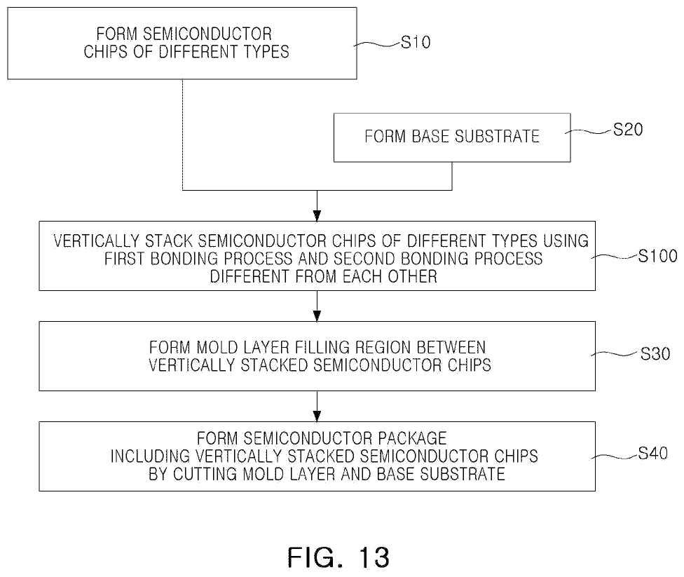

In the description below, an example embodiment of a method of manufacturing a semiconductor package according to an example embodiment will be described with reference to FIG. 13. FIG. 13 illustrates a flowchart illustrating an example method of manufacturing a semiconductor package according to an example embodiment.

Referring to FIG. 13, semiconductor chips of different types may be formed (S10).

The semiconductor chips of the different types may be at least two of the A-type semiconductor chip CH_A, the B-type semiconductor chip CH_B, the C-type semiconductor chip CH_C, the D-type semiconductor chip CH_D, the E-type semiconductor chip CH_E, and the F-type semiconductor chip CH_F, described with reference to FIGS. 1A, 1B and 1C.

A base substrate may be formed (S20). In an example, at least a portion of the base substrate may be substantially the same as the lower chip LCa, LCc, LCe, and LCg as described with reference to FIGS. 2A, 6, 8, and 10. In another example, at least a portion of the base substrate may be substantially the same as the lower chip LCb, LCd, LCf, and LCh as described with reference to FIGS. 4, 7, 9, and 11.

Semiconductor chips of different types may be vertically stacked using different first and second bonding processes (S100).

The first bonding process may be a process for forming the first bonding chips BS1 bonded to each other by the bumps BP described with reference to FIGS. 2A to 11. The second bonding process may be a process for forming the directly bonded second bonding chips BS2 described with reference to FIGS. 2A to 11.

The first bonding process may be a thermal compression bonding process, and the second bonding process may be a hybrid metal bonding process. Here, the hybrid metal bonding process may be a direct bonding process of directly bonding a metal to a metal, and directly bonding an insulating layer to an insulating layer.

A mold layer filling a region between the vertically stacked semiconductor chips may be formed (S30). A semiconductor package including vertically stacked semiconductor chips may be formed by cutting the mold layer and the base substrate (S40).

By various combinations of different types of the semiconductor chips and various combinations of the order of the first bonding process and the second bonding process, the semiconductor packages 1a, 1b, 1c, 1d, 1e, 1f, 1g, and 1h may be formed.

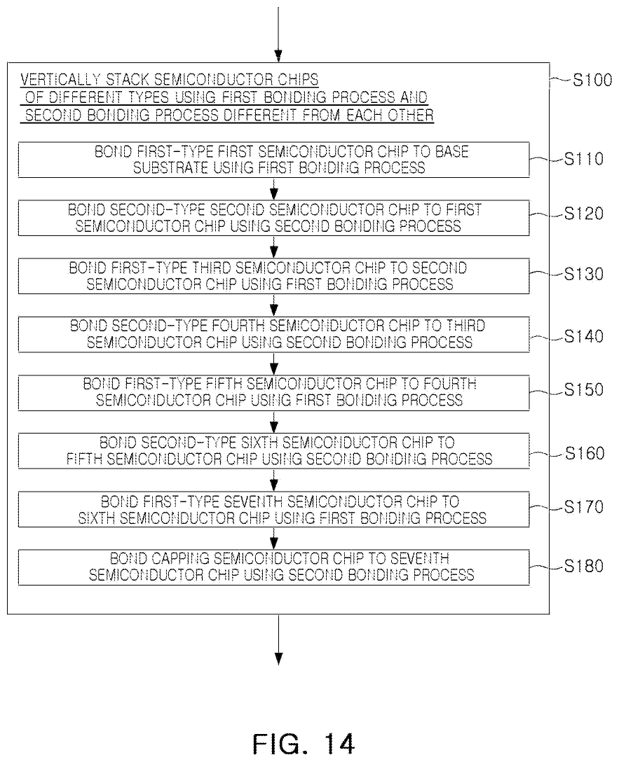

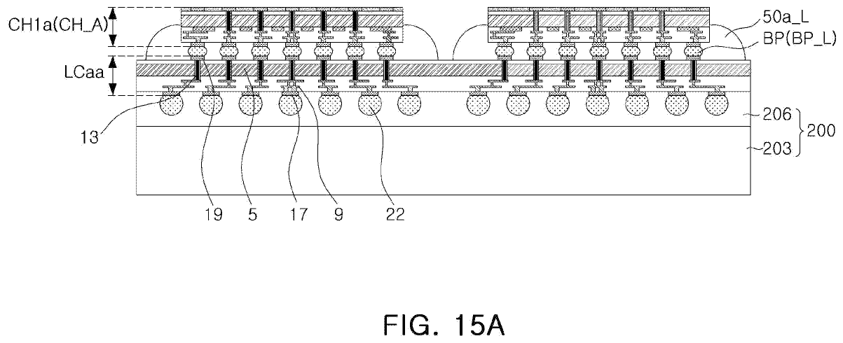

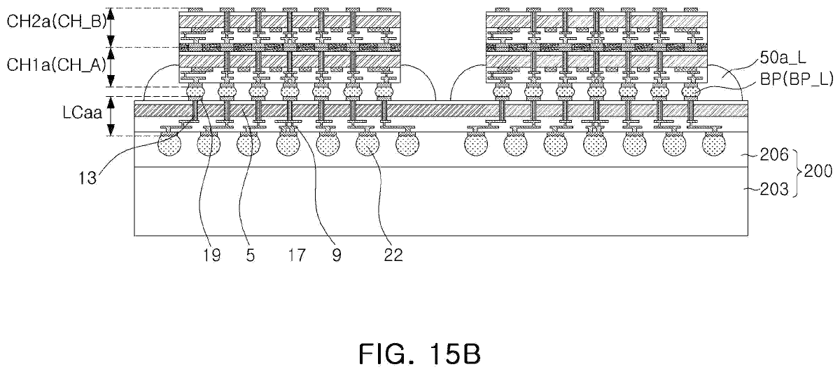

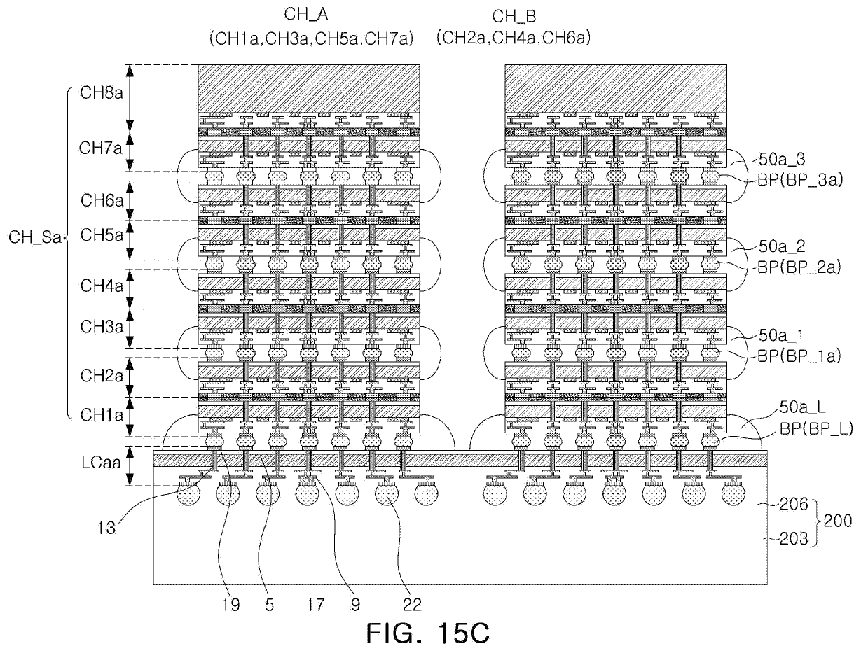

An example embodiment of a method of manufacturing the semiconductor package 1a described with reference to FIGS. 2A to 2C will be described with reference to FIGS. 14 and 15A to 15C together with FIG. 13. FIG. 14 is a flowchart illustrating an example method of manufacturing a semiconductor package according to an example embodiment, and FIGS. 15A to 15C are flowcharts illustrating an example method of manufacturing a semiconductor package according to an example embodiment.

Referring to FIGS. 13, 14, and 15A, semiconductor chips of different types may be formed (S10). The semiconductor chips of different types may be the A-type semiconductor chip CH_A and the B-type semiconductor chip CH_B described with reference to FIG. 1A.

A base substrate LCaa may be formed (S20). The base substrate LCaa may be disposed on a carrier substrate 200. The carrier substrate 200 may include a support substrate 203 and an adhesive material layer 206 on the support substrate 203.

The base substrate LCaa may include a body portion, a lower pad 17 below the body portion, and an upper pad 19 on the body portion. The body portion may include a substrate 5, interconnections 9 disposed below the substrate 5, and a through-electrode structure 13 penetrating the substrate 5 and electrically connected to the interconnections 9.

A connection bump 22 may be disposed below the lower pad 17 of the base substrate LCaa. A lower surface of the base substrate LCaa may be adhered to the adhesive material layer 206, and the connection bump 22 may be covered by the adhesive material layer 206. For example, the connection bump 22 may be surrounded by the adhesive material layer 206.

A first-type first semiconductor chip CH1a may be bonded to the base substrate LCaa through a first bonding process (S110). The first semiconductor chip CH1a may be bonded to the base substrate LCaa by the lower bump BP_L.

The first semiconductor chip CH1a may be the first chip CH1a in FIGS. 2A to 2C or may be the A-type semiconductor chip CH_A.

The first bonding process may be a thermal compression bonding process for bonding two chips using bumps. The first bonding process may include forming a solder bump on a lower surface of an upper chip among the two chips, forming an adhesive film in contact with a lower surface of the upper chip and surrounding the solder bump, and bonding the solder bump of the upper chip to the lower chip while applying pressure in the downward direction on the upper chip in a thermal atmosphere. Here, the upper chip may be the first semiconductor chip CH1a, the lower chip may be the base substrate LCaa, and the adhesive film may be the lower adhesive film 50a_L.

Referring to FIGS. 13, 14, and 15B, a second-type second semiconductor chip CH2a may be bonded to the first semiconductor chip CH1a by a second bonding process (S120). The second bonding process may be a hybrid metal bonding process. Here, the hybrid metal bonding process may be a direct bonding process of directly bonding a metal to a metal, and directly bonding an insulating layer to an insulating layer. The second semiconductor chip CH2a may be the second chip CH2a in FIGS. 2A to 2C, and may be the B-type semiconductor chip CH_B described with reference to FIG. 1A.

Referring to FIGS. 13, 14, and 15C, a first-type third semiconductor chip CH3a may be bonded to the second semiconductor chip CH2a by the first bonding process (S130). A second-type fourth semiconductor chip CH4a may be bonded to the third semiconductor chip CH3a through the second bonding process (S140). A first-type fifth semiconductor chip CH5a may be bonded to the fourth semiconductor chip CH4a by the first bonding process (S150). A second-type sixth semiconductor chip CH6a may be bonded to the fifth semiconductor chip CH5a by the second bonding process (S160). A first-type seventh semiconductor chip CH7a may be bonded to the sixth semiconductor chip CH6a by the first bonding process (S170). The capping semiconductor chip CH8a may be bonded to the seventh semiconductor chip CH7a by the second bonding process (S180).

The third semiconductor chip CH3a, the fifth semiconductor chip CH5a, and the seventh semiconductor chip CH7a may be the A-type semiconductor chip CH_A described with reference to FIG. 1A.

The fourth semiconductor chip CH4a and the sixth semiconductor chip CH6a may be the B-type semiconductor chip CH_B described with reference to FIG. 1A.

The capping semiconductor chip CH8a may be referred to as an eighth semiconductor chip.

In an example, the capping semiconductor chip CH8a may be substantially the same as the B-type semiconductor chip CH_B described with reference to FIG. 1A. In another example, the capping semiconductor chip CH8a may be a capping semiconductor chip in which the through-electrode structure 42 and the first bonding pad PD_Bb may not be provided, and the semiconductor substrate 32 may have an increased thickness in the B-type semiconductor chip CH_B.

By the first bonding process, which may be a thermal compression bonding process, two chips may be bonded to each other by a bump BP, an adhesive film may be filled between the two chips, and the adhesive film may extend over the side surfaces of the two chips. For example, a first bump BP_1a may be formed between the second semiconductor chip CH2a and the third semiconductor chip CH3a, and a first adhesive film 50a_1 filling the region between the second and third semiconductor chips CH2a and CH3a and extending to side surfaces of the second and third semiconductor chips CH2a and CH3a may be formed. The first adhesive film 50a_1 may surround the first bump BP_1a. Similarly, a second bump BP_2a may be formed between the fourth and fifth semiconductor chips CH4a and CH5a and a second adhesive film 50a_2 filling the region between the fourth and fifth semiconductor chips CH4a and CH5a and extending to side surfaces of the fourth and fifth semiconductor chips CH4a and CH5a may be formed. The second adhesive film 50a_2 may surround the second bump BP_2a. In addition, a third bump BP_3a may be formed between the sixth and seventh semiconductor chips CH6a and CH7a, and a third adhesive film 50a_3 filling the region between the sixth and seventh semiconductor chips CH6a and CH7a, and extending to side surfaces of the sixth and seventh semiconductor chips CH6a and CH7a may be formed. The third adhesive film 50a_3 may surround the third bump BP_3a.

Accordingly, a stack chip structure CH_Sa including the vertically stacked first to eighth semiconductor chips CH1a, CH2a, CH3a, CH4a, CH5a, CH6a, CH7a, and CH8a may be formed.

A mold layer filling a region between the vertically stacked first to eighth semiconductor chips CH1a, CH2a, CH3a, CH4a, CH5a, CH6a, CH7a, and CH8a may be formed (S30). Here, a plurality of the stack chip structures CH_Sa may be disposed on the base substrate 200, and the mold layer may be disposed between the plurality of stack chip structures CH_Sa.

Thereafter, by cutting the mold layer and the base substrate 200, the semiconductor package 1a (in FIGS. 2A to 2C) including the first to eighth semiconductor chips CH1a, CH2a, CH3a, CH4a, CH5a, CH6a, CH7a, and CH8a stacked vertically may be formed (S40).

In the above-described embodiment, among bonding processes in which the first bonding process and the second bonding process are repeatedly performed, the first-type semiconductor chip, in other words, the A-type semiconductor chip CH_A described with reference to FIG. 1A may be first stacked on the base substrate 200 using the first bonding process, but an example embodiment thereof is not limited thereto. For example, among bonding processes in which the first bonding process and the second bonding process are repeatedly performed, the processes may be performed in the order in which the second-type semiconductor chip, in other words, the B-type semiconductor chip described with reference to FIG. 1A may be stacked using the second bonding process, such that the semiconductor package 1b as described with reference to FIG. 4 may be formed.

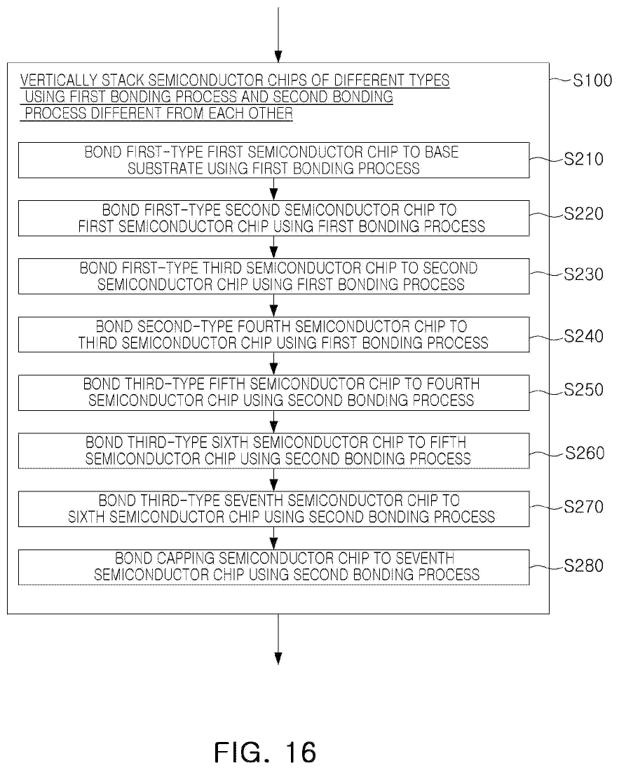

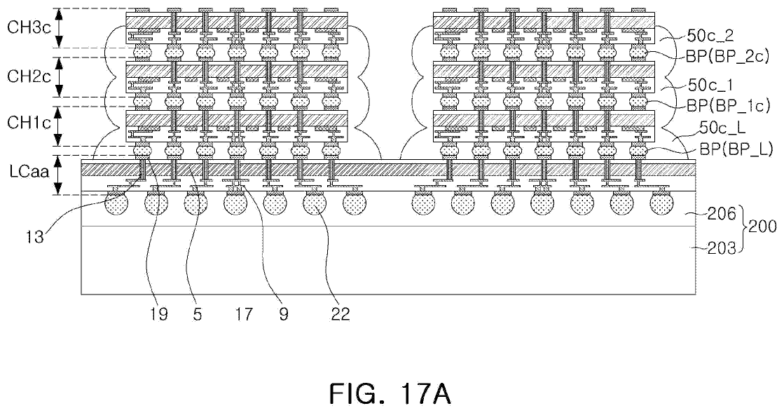

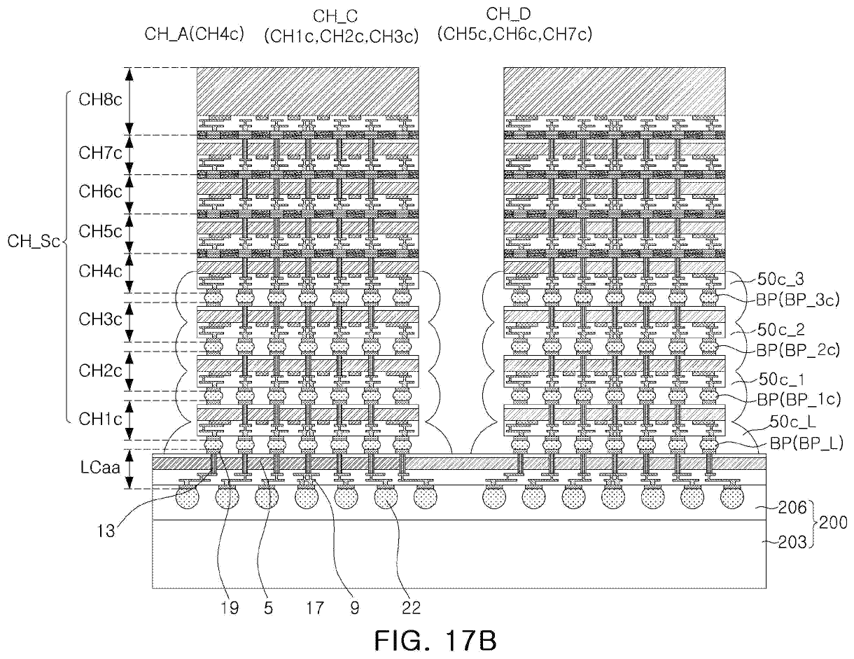

In the description below, an example method of manufacturing the semiconductor package 1c described with reference to FIG. 6 will be described with reference to FIGS. 16, 17A, and 17BC along with FIG. 13. FIG. 16 is a flowchart illustrating an example of a method of manufacturing a semiconductor package according to an example embodiment, and FIGS. 17A and 17B are flowcharts illustrating an example of a method of manufacturing a semiconductor package according to an example embodiment process.

Referring to FIGS. 13, 16, and 17A, semiconductor chips of different types may be formed (S10). The semiconductor chips of different types may be the A-type semiconductor chip CH_A, the C-type semiconductor chip CH_C, and the D-type semiconductor chip CH_D described with reference to FIGS. 1A and 1B.

The base substrate LCaa as described with reference to FIG. 15A may be formed (S20). As illustrated in FIG. 15A, the base substrate LCaa may be disposed on the carrier substrate 200.

A first-type first semiconductor chip CH1c may be bonded to the base substrate LCaa through a first bonding process (S210). The first semiconductor chip CH1c may be bonded to the base substrate LCaa by the lower bump BP_L.

By performing the first bonding process described above, the first semiconductor chip CH1c may be bonded to the base substrate LCaa by the lower bump BP_L, and a lower adhesive film 50c_L filling a region between the first semiconductor chip CH1c and the base substrate LCaa and extending to a side surface of the first semiconductor chip CH1c may be formed.

A first-type second semiconductor chip CH2c may be bonded to the first semiconductor chip CH1c through a first bonding process (S220). A first-type third semiconductor chip CH3c may be bonded to the second semiconductor chip CH2c through a first bonding process (S230).

The first to third semiconductor chips CH1c, CH2c, and CH3c may be the C-type semiconductor chip CH_C.

By performing the first bonding process, which may be the above-described thermal compression bonding process, the second semiconductor chip CH2c may be bonded to the first semiconductor chip CH1c by a first bump BP_1c, and a first adhesive film 50c_1 filling a region between the first and second semiconductor chips CH1c and CH2c, and extending to side surfaces of the first and second semiconductor chips CH1c and CH2c may be formed.

By performing the first bonding process, the third semiconductor chip CH3c may be bonded to the second semiconductor chip CH2c by a second bump BP_2c, and a second adhesive film 50c_2 filling a region between the second and third semiconductor chips CH2c and CH3c and extending to the side surfaces of the second and third semiconductor chips CH2c and CH3c may be formed.

Referring to FIGS. 13, 16, and 17B, a second-type fourth semiconductor chip CH4c may be bonded to the third semiconductor chip CH3c by a first bonding process (S240).

By performing the first bonding process, the fourth semiconductor chip CH4c may be bonded to the third semiconductor chip CH3c by a third bump BP_3c, and a third adhesive film 50c_3 filling a region between the third and fourth semiconductor chips CH3c and CH4c and extending to side surfaces of the third and fourth semiconductor chips CH3c and CH4c may be formed.

The fourth semiconductor chip CH4c may be the A-type semiconductor chip CH_A.

A third-type fifth semiconductor chip CH5c may be bonded to the fourth semiconductor chip CH4c by a second bonding process (S250). A third-type sixth semiconductor chip CH6c may be bonded to the fifth semiconductor chip CH5c by a second bonding process (S260). A third-type seventh semiconductor chip CH7c may be bonded to the sixth semiconductor chip CH6c by a second bonding process (S270). The capping semiconductor chip CH8c may be bonded to the seventh semiconductor chip CH7c by a second bonding process (S280). The second bonding process may be a hybrid metal bonding process as described above.

The fifth to seventh semiconductor chips CH5c, CH6c, and CH7c may be the D-type semiconductor chip CH_D.

The capping semiconductor chip CH8c may be referred to as an eighth semiconductor chip. In an example, the capping semiconductor chip CH8c may be substantially the same as the D-type semiconductor chip CH_D. In another example, the capping semiconductor chip CH8c may be a semiconductor chip in which the through-electrode structure 42, the second bonding pad PD_Db, and the second bonding insulating layer IN_Db are not provided and the semiconductor substrate 32 may have an increased thickness in the D-type semiconductor chip CH_D.

Accordingly, a stack chip structure CH_Sc including the vertically stacked first to eighth semiconductor chips CH1c, CH2c, CH3c, CH4c, CH5c, CH6c, CH7c, and CH8c may be formed.

A mold layer filling a region between the vertically stacked first to eighth semiconductor chips CH1c, CH2c, CH3c, CH4c, CH5c, CH6c, CH7c, and CH8c may be formed (S30). Here, a plurality of the stack chip structures CH_Sc may be disposed on the base substrate 200, and the mold layer may be disposed between the plurality of stack chip structures CH_Sc.

Thereafter, by cutting the mold layer and the base substrate 200, A semiconductor package 1c (in FIG. 6) including the vertically stacked first to eighth semiconductor chips CH1c, CH2c, CH3c, CH4c, CH5c, CH6c, CH7c, and CH8c may be formed (S40).

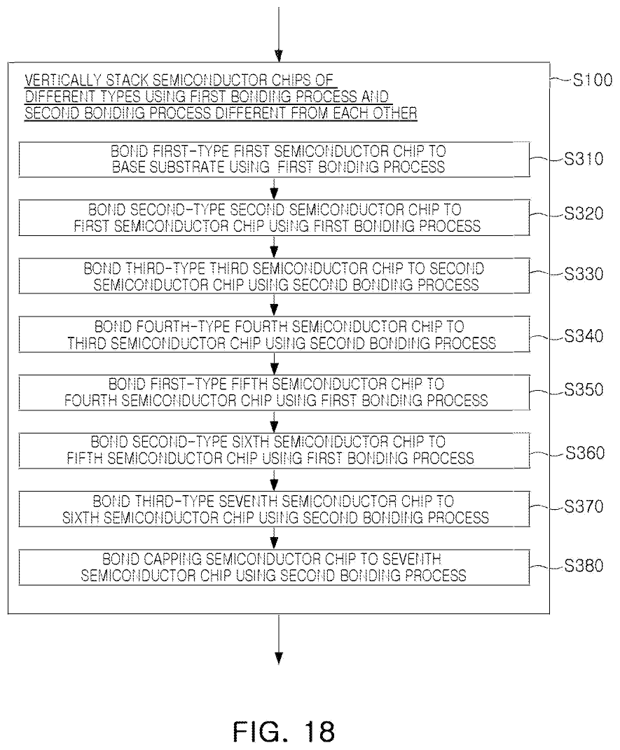

In the description below, an example method of manufacturing the semiconductor package 1d described with reference to FIG. 8 will be described with reference to FIG. 18. FIG. 18 is a flowchart illustrating an example of a method of manufacturing a semiconductor package according to an example embodiment.

Referring to FIG. 18 together with FIG. 8, semiconductor chips of different types may be formed (S10). The semiconductor chips of different types may be the A-type semiconductor chip CH_A, the B-type semiconductor chip CH_B, the C-type semiconductor chip CH_C, and the D-type semiconductor chip CH_D described with reference to FIGS. 1A and 1B.

The forming the stack chip structure CH_Se as in FIG. 8 may include repeatedly performing the above-described first bonding process multiple times and performing the above-described second bonding process multiple times. For example, a first-type first chip CH1e may be bonded to the base substrate (LCaa in FIG. 15A) as described above by the first bonding process (S310), the second-type second chip CH2e may be bonded to the first chip CH1e by the first bonding process (S320), the third-type third chip CH3e may be bonded to the second chip CH2e through the second bonding process bonding (S330), the fourth-type fourth chip CH4e may be bonded to the third chip CH3e by the second bonding process (S340), and the first-type fifth chip CH5e may be bonded to the fourth chip CH4e by the first bonding process (S350), the second-type sixth chip CH6e may be bonded to the fifth chip CH5e by the first bonding process (S360), the third-type seventh chip CH7e may be bonded to the sixth chip CH6e by the second bonding process (S370), and the capping semiconductor chip CH8e may be bonded to the seventh chip CH7e using the second bonding process (S380).

The first and fifth chips CH1e and CH5e may be the C-type semiconductor chip CH_C, and the second and sixth chips CH2e and CH6e may be the A-type semiconductor chip CH_A, the third and seventh chips CH3e and CH7e may be the D-type semiconductor chip CH_D, and the fourth chip CH4e may be the B-type semiconductor chip CH_B.

According to the aforementioned example embodiments, the semiconductor package may include semiconductor chips including first bonding chips bonded to each other by a bump and second bonding chips directly bonded to each other. The first bonding chips bonded to each other by the bump may be formed by a first bonding process which may be a thermal compression bonding process, and the directly bonded second bonding chips may be formed by a second bonding process which may be a hybrid metal bonding process. By including the first bonding chips and the second bonding chips, thermal properties in a vertical direction in the semiconductor package may improve and yield may improve.

While the example embodiments have been illustrated and described above, it will be apparent to those skilled in the art that modified examples and variations could be made without departing from the scope of the present disclosure as set forth by the appended claims.

1. A semiconductor package, comprising:
a lower chip;
a stack chip structure on the lower chip, the stack chip structure including semiconductor chips stacked in a direction perpendicular to an upper surface of the lower chip; and
an adhesive film,
wherein the semiconductor chips include first bonding chips bonded to each other by bumps and second bonding chips directly bonded to each other,
wherein the first bonding chips include:
a first bonding lower chip including a first bonding upper pad in contact with and bonded to the bumps; and
a first bonding upper chip disposed on the first bonding lower chip and including a first bonding lower pad in contact with and bonded to the bumps,
wherein the second bonding chips include:
a second bonding lower chip including a second bonding upper insulating layer and a second bonding upper pad; and
a second bonding upper chip disposed on the second bonding lower chip and including a second bonding lower insulating layer in contact with and bonded to the second bonding upper insulating layer, and a second bonding lower pad in contact with and bonded to the second bonding upper pad, and
wherein the adhesive film surrounds side surfaces of the bumps, fills a region between the first bonding lower chip and the first bonding upper chip, and protrudes from the region between the first bonding lower chip and the first bonding upper chip.

2. The semiconductor package of claim 1,
wherein at least one of the first bonding lower pad and the first bonding upper pad has a first thickness,
wherein at least one of the second bonding lower pad and the second bonding upper pad has a second thickness, and
wherein the first thickness is greater than the second thickness.

3. The semiconductor package of claim 2,
wherein the first thickness is about 2 μm to about 5 μm, and
wherein the second thickness is about 0.3 μm to about 0.9 μm.

4. The semiconductor package of claim 1,
wherein each of the first bonding lower pad and the first bonding upper pad includes a first metal, and
wherein each of the second bonding lower pad and the second bonding upper pad includes a second metal different from the first metal.

5. The semiconductor package of claim 4,
wherein the first metal includes Ni, Au, or Ti, and
wherein the second metal includes Cu.

6. The semiconductor package of claim 1, wherein one of the first bonding chips and one of the second bonding chips are the same chip.

7. The semiconductor package of claim 6, wherein the first bonding upper chip and the second bonding lower chip are the same chip.

8. The semiconductor package of claim 6, wherein the second bonding upper chip and the first bonding lower chip are the same chip.

9. The semiconductor package of claim 1,
wherein the semiconductor chips include a first chip, a second chip, a third chip, a fourth chip, a fifth chip, a sixth chip, a seventh chip, and an eighth chip stacked in order in the direction perpendicular to the upper surface of the lower chip,
wherein the first chip and the second chip are directly bonded to each other, and are included in the second bonding chips,
wherein the second chip and the third chip are bonded to each other by a first bump, and are included in the first bonding chips,
wherein the third chip and the fourth chip are directly bonded to each other, and are included in the second bonding chips,
wherein the fourth chip and the fifth chip are bonded to each other by a second bump, and are included in the first bonding chips,
wherein the fifth chip and the sixth chip are directly bonded to each other, and are included in the second bonding chips,
wherein the sixth chip and the seventh chip are bonded to each other by a third bump, and are included in the first bonding chips, and
wherein the seventh chip and the eighth chip are directly bonded to each other, and are included in the second bonding chips.

10. The semiconductor package of claim 9,
wherein the adhesive film includes:
a first adhesive film covering a side surface of the first bump, filling a region between the second chip and the third chip, and protruding from side surfaces of the second and third chips;
a second adhesive film covering a side surface of the second bump, filling a region between the fourth chip and the fifth chip, and protruding from side surfaces of the fourth and fifth chips; and
a third adhesive film covering a side surface of the third bump, filling a region between the sixth chip and the seventh chip, and protruding from side surfaces of the sixth and seventh chips, and
wherein the first adhesive film, the second adhesive film, and the third adhesive film are spaced apart from each other.

11. The semiconductor package of claim 9,
wherein the adhesive film includes:
a first adhesive film covering a side surface of the first bump, filling a region between the second chip and the third chip, and disposed on side surfaces of the second and third chips;
a second adhesive film covering a side surface of the second bump, filling a region between the fourth chip and the fifth chip, and disposed on side surfaces of the fourth and fifth chips; and
a third adhesive film covering a side surface of the third bump, filling a region between the sixth chip and the seventh chip, and disposed on side surfaces of the sixth and seventh chips, and
wherein the first adhesive film, the second adhesive film and the third adhesive film are connected to each other.

12. The semiconductor package of claim 1,
wherein the semiconductor chips include a first chip, a second chip, a third chip, a fourth chip, a fifth chip, a sixth chip, a seventh chip, and an eighth chip stacked in order in the direction perpendicular to the upper surface of the lower chip,
wherein the first chip and the second chip are bonded to each other by a first bump, and are included in the first bonding chips,
wherein the second chip and the third chip are directly bonded to each other, and are included in the second bonding chips,
wherein the third chip and the fourth chip are bonded to each other by a second bump, and are included in the first bonding chips,
wherein the fourth chip and the fifth chip are directly bonded to each other, and are included in the second bonding chips,
wherein the fifth chip and the sixth chip are bonded to each other by a third bump, and are included in the first bonding chips,
wherein the sixth chip and the seventh chip are directly bonded to each other, and are included in the second bonding chips, and
wherein the seventh chip and the eighth chip are bonded to each other by a fourth bump, and are included in the first bonding chips.

13. The semiconductor package of claim 1,
wherein the semiconductor chips include a first chip, a second chip, a third chip, a fourth chip, a fifth chip, a sixth chip, a seventh chip, and an eighth chip stacked in order in the direction perpendicular to the upper surface of the lower chip,
wherein the first chip and the second chip are bonded to each other by a first bump, and are included in the first bonding chips,
wherein the second chip and the third chip are bonded to each other by a second bump, and are included in the first bonding chips,
wherein the third chip and the fourth chip are bonded to each other by a third bump, and are included in the first bonding chips,
wherein the fourth chip and the fifth chip are directly bonded to each other, and are included in the second bonding chips,
wherein the fifth chip and the sixth chip are directly bonded to each other, and are included in the second bonding chips,
wherein the sixth chip and the seventh chip are directly bonded to each other, and are included in the second bonding chips, and
wherein the seventh chip and the eighth chip are directly bonded to each other, and are included in the second bonding chips.

14. The semiconductor package of claim 1,
wherein the semiconductor chips include a first chip, a second chip, a third chip, a fourth chip, a fifth chip, a sixth chip, a seventh chip, and an eighth chip stacked in order in the direction perpendicular to the upper surface of the lower chip,
wherein the first chip and the second chip are directly bonded to each other, and are included in the second bonding chips,
wherein the second chip and the third chip are directly bonded to each other, and are included in the second bonding chips,
wherein the third chip and the fourth chip are directly bonded to each other, and are included in the second bonding chips,
wherein the fourth chip and the fifth chip are bonded to each other by a first bump, and are included in the first bonding chips,
wherein the fifth chip and the sixth chip are bonded to each other by a second bump, and are included in the first bonding chips,
wherein the sixth chip and the seventh chip are bonded to each other by a third bump, and are included in the first bonding chips, and
wherein the seventh chip and the eighth chip are bonded to each other by a fourth bump, and are included in the first bonding chips.

15. The semiconductor package of claim 1,
wherein the first bonding chips are repeatedly stacked,
wherein the second bonding chips are repeatedly stacked, and
wherein the repeatedly stacked first bonding chips and the repeatedly stacked second bonding chips are repeatedly stacked two or more times.

16. The semiconductor package of claim 1, wherein each of the semiconductor chips includes a semiconductor substrate and an internal circuit region disposed below the semiconductor substrate.

17. The semiconductor package of claim 1,
wherein the semiconductor chips include a first-type semiconductor chip and a second-type semiconductor chip different from the first-type semiconductor chip, and
wherein the first-type semiconductor chip includes a first semiconductor substrate and a first internal circuit region disposed below the first semiconductor substrate, and
wherein the second type semiconductor chip includes a second semiconductor substrate and a second internal circuit region disposed above the second semiconductor substrate.

18. A semiconductor package, comprising:
a lower chip;
a stack chip structure on the lower chip, the stack chip structure including semiconductor chips stacked in a direction perpendicular to an upper surface of the lower chip; and
an adhesive film,
wherein the semiconductor chips include first bonding chips bonded to each other by a bump and second bonding chips directly bonded to each other,
wherein the first bonding chips include a first bonding lower chip and a first bonding upper chip connected to the first bonding lower chip by the bump on the first bonding lower chip,
wherein the second bonding chips include a second bonding lower chip and a second bonding upper chip directly bonded to the second bonding lower chip,
wherein the adhesive film surrounds a side surface of the bump, fills a region between the first bonding lower chip and the first bonding upper chip, and protrudes from side surfaces of at least one of the first bonding lower chip and the first bonding upper chip,
wherein one of the first bonding chips and one of the second bonding chips are the same and constitute a shared chip,
wherein the shared chip includes:
a body portion having a first side and a second side opposite to each other;
a first bonding pad disposed on the first side of the body portion; and
a second bonding pad and a second bonding insulating layer disposed on the second side of the body portion,
wherein the first bonding pad is in contact with the bump,
wherein the first bonding pad has a first thickness, and
wherein the second bonding pad has a second thickness different from the first thickness.

19. The semiconductor package of claim 18,
wherein the first thickness is about 2 μm to about 5 μm, and
wherein the second thickness is about 0.3 μm to about 0.9 μm.

20. A semiconductor package, comprising:
a lower chip; and
a stack chip structure on the lower chip, the stack chip structure including semiconductor chips stacked in a direction perpendicular to an upper surface of the lower chip,
wherein the semiconductor chips include first bonding chips bonded to each other by a bump and second bonding chips directly bonded to each other,
wherein each of the semiconductor chips includes a body portion including a semiconductor substrate and an internal circuit region disposed below the semiconductor substrate,
wherein a first semiconductor chip of the semiconductor chips further includes a first bonding pad disposed on a first side of the body portion, and a second bonding pad and a second bonding insulating layer disposed on a second side of the body portion,
wherein the second bonding insulating layer covers at least a portion of a side surface of the second bonding pad,
wherein a thickness of the first bonding pad is about 2 μm to about 5 μm, and
wherein a thickness of the second bonding pad is about 0.3 μm to about 0.9 μm.

21-26. (canceled)
